(19) United States
(12) Patent Application Publication
(10) Pub. No.: US 2025/0336705 A1
(43) Pub. Date: Oct. 30, 2025

(54) WAFER PROCESSING APPARATUS, SEMICONDUCTOR CHIP MANUFACTURING METHOD, AND SEMICONDUCTOR CHIP

(71) Applicant: YAMAHA HATSUDOKI KABUSHIKI KAISHA, Iwata-shi, Shizuoka-ken (JP)

(72) Inventor: Yoshikuni SUZUKI, Iwata-shi, Shizuoka (JP)

(73) Assignee: YAMAHA HATSUDOKI KABUSHIKI KAISHA, Iwata-shi, Shizuoka-ken (JP)

(21) Appl. No.: 18/855,543

(22) PCT Filed: Feb. 3, 2023
(86) PCT No.: PCT/JP2023/003613

§ 371 Date: Oct. 9, 2024

(30) Foreign Application Priority Data
Apr. 27, 2022 (WO) PCT/JP2022/019154

(51) Int. Cl. H01L 21/677; H01L 21/67; H01L 21/683

(52) U.S. Cl. CPC H01L 21/67718; H01L 21/67092; H01L 21/67109; H01L 21/67132; H01L 21/67769; H01L 21/6836; H01L 21/6838; H01L 2221/68336

(57) ABSTRACT

A wafer processing apparatus includes a wafer storage configured to store a wafer structure, a dicer configured to perform dicing on a wafer of the wafer structure supplied from the wafer storage, and a wafer transporter configured to transport the wafer structure between the wafer storage and the dicer. The wafer transporter includes an inversion mechanism configured to invert a posture of the wafer structure.

### CROSS-REFERENCE TO RELATED APPLICATION

This application is a National Stage of International Patent Application No. PCT/JP2022/019154, filed Apr. 27, 2022, the entire content of which is incorporated herein by reference.

### BACKGROUND

### Technical Field

The present disclosure relates to a wafer processing apparatus, a semiconductor chip manufacturing method, and a semiconductor chip, and more particularly, the present disclosure relates to a wafer processing apparatus that processes a wafer on which a plurality of semiconductor chips have been formed, a semiconductor chip manufacturing method, and a semiconductor chip.

### Background Art

Conventionally, a wafer processing apparatus that processes a wafer on which a plurality of semiconductor chips have been formed is known. Such a wafer processing apparatus is disclosed in Japanese Patent No. 6904368, for example.

Japanese Patent No. 6904368 discloses a wafer processing apparatus that processes a wafer on which a plurality of integrated circuit chips have been formed. In the wafer processing apparatus, the wafer is diced. Specifically, after the wafer is inverted, dicing is performed on the back surface of the wafer.

### SUMMARY

Although not clearly described in Japanese Patent No. 6904368, an inversion mechanism that inverts the wafer is conceivably provided in the wafer processing apparatus described in the Japanese Patent No. 6904368. However, when the inversion mechanism is provided separately and independently, the structure becomes complex.

Therefore, the present disclosure provides a wafer processing apparatus, a semiconductor chip manufacturing method, and a semiconductor chip that each allow an inversion mechanism to invert a wafer structure while reducing or preventing the complexity of the structure.

A wafer processing apparatus according to a first aspect of the present disclosure includes a wafer storage configured to store a wafer structure including a wafer on which a plurality of semiconductor chips have been formed and a sheet member to which the wafer has been attached, a dicer configured to perform dicing to divide the wafer of the wafer structure supplied from the wafer storage into individual semiconductor chips, and a wafer transporter configured to transport the wafer structure between the wafer storage and the dicer. The wafer transporter includes an inversion mechanism configured to invert a posture of the wafer structure.

In the wafer processing apparatus according to the first aspect of the present disclosure, as described above, the wafer transporter includes the inversion mechanism that inverts the posture of the wafer structure. Accordingly, the inversion mechanism is provided by effectively using the wafer transporter, and thus it is not necessary to provide the inversion mechanism separately and independently. Consequently, the complexity of the structure can be reduced or prevented. Furthermore, the wafer structure can be inverted by the inversion mechanism. Consequently, the wafer structure can be inverted by the inversion mechanism while the complexity of the structure is reduced or prevented.

In the wafer processing apparatus according to the first aspect, the wafer transporter preferably further includes a suction unit configured to suction the wafer structure, and the inversion mechanism is preferably configured to invert the posture of the wafer structure by rotating the suction unit that is suctioning the wafer structure about a rotation axis extending in a horizontal direction. Accordingly, the wafer can be reliably held by suction, and thus the wafer can be stably inverted and transported.

In the wafer processing apparatus according to the first aspect, the wafer storage is preferably configured to store the wafer structure that does not include a ring-shaped member surrounding the wafer, and the wafer transporter is preferably configured to invert the wafer structure using the inversion mechanism and supply the wafer structure to the dicer. In the case of the wafer structure that does not include a ring-shaped member, the wafer may not be supplied in a posture suitable for dicing. Therefore, with the configuration described above, even in the case of the wafer structure that does not include a ring-shaped member, in which the wafer is not supplied in a posture suitable for dicing, the wafer can be placed in a posture suitable for dicing by inverting the wafer structure using the inversion mechanism, and thus dicing can be performed appropriately.

In such a case, the wafer processing apparatus preferably further includes a temporary placement unit provided between the wafer storage and the dicer and configured to allow the wafer structure to be placed thereon, and the wafer transporter is preferably configured to invert the wafer structure using the inversion mechanism and place the wafer structure on the temporary placement unit before supplying the wafer structure to the dicer. Accordingly, the next wafer can be prepared in an inverted state on the temporary placement unit, and thus the next wafer can be quickly supplied to the dicer.

The wafer processing apparatus according to the first aspect preferably further includes an expander configured to expand the sheet member to which the wafer diced by the dicer has been attached. The wafer transporter is preferably configured to transport the wafer structure between the dicer and the expander, the wafer storage is preferably configured to store the wafer structure including a ring-shaped member surrounding the wafer, and the wafer transporter is preferably configured to supply the wafer structure to the dicer without inverting the wafer structure using the inversion mechanism, and to invert the wafer structure using the inversion mechanism and supply the wafer structure to the expander. In the case of the wafer structure including the ring-shaped member, the wafer is supplied in a posture suitable for dicing. However, when the posture of the wafer suitable for dicing is opposite to the posture of the wafer suitable for expansion, the posture of the wafer suitable for dicing does not match the posture of the wafer suitable for expansion. Therefore, with the configuration described above, even in the case of the wafer structure including the ring-shaped member, in which the posture of the wafer suitable for dicing does not match the posture of the wafer suitable for expansion, the wafer structure is inverted by the inversion mechanism such that dicing and expansion can be appropriately performed.

In such a case, the expander preferably includes a cooler configured to cool the sheet member when expanding the sheet member, and the wafer transporter is preferably configured to invert the wafer structure using the inversion mechanism and deliver the wafer structure to the cooler. Accordingly, the wafer is delivered by effectively using the cooler, and thus it is not necessary to provide a receiving portion for the wafer independent of the cooler. Consequently, the complexity of the structure can be reduced or prevented as compared with a case in which a receiving portion for the wafer is provided independent of the cooler.

In the wafer processing apparatus according to the first aspect, the wafer storage is preferably configured to store the wafer structure including a ring-shaped member surrounding the wafer, and the wafer transporter is preferably configured to invert the wafer structure using the inversion mechanism and supply the wafer structure to the dicer. In the case of the wafer structure including the ring-shaped member, the wafer may not be supplied in a posture suitable for dicing. Therefore, with the configuration described above, even in the case of the wafer structure including the ring-shaped member, in which the wafer is not supplied in a posture suitable for dicing, the wafer can be placed in a posture suitable for dicing by inverting the wafer structure using the inversion mechanism, and thus dicing can be performed appropriately.

In the wafer processing apparatus according to the first aspect, the wafer transporter preferably includes a taking-out unit configured to take out the wafer structure from the wafer storage, and a transport mechanism configured to transport a taken-out wafer structure, and the inversion mechanism is preferably provided in the transport mechanism. Accordingly, the taking-out unit and the transport mechanism are provided separately from each other, and thus the wafer structure can be easily taken out from the water storage, and the taken-out wafer structure can be easily transported. Furthermore, the inversion mechanism is provided in the transport mechanism such that the wafer structure can be easily inverted by the inversion mechanism.

In the wafer processing apparatus according to the first aspect, the wafer transporter preferably includes a take-out transporter configured to take out the wafer structure from the wafer storage and transport a taken-out wafer structure, and the inversion mechanism is preferably provided in the take-out transporter. Accordingly, using the take-out transporter, the wafer structure can be easily taken out from the wafer storage, and the taken-out wafer structure can be easily transported.

In the wafer processing apparatus according to the first aspect, the wafer transporter preferably includes a conveyor configured to take out the wafer structure from the wafer storage and transport a taken-out wafer structure, and the inversion mechanism is preferably provided as a portion of the conveyor. Accordingly, the inversion mechanism is provided as a portion of the conveyor by effectively using the conveyor that takes out the wafer structure from the wafer storage, and thus as compared with a case in which the inversion mechanism is provided separately and independently, the complexity of the structure can be reduced or prevented. Furthermore, the posture of the wafer structure can be inverted while the wafer structure is transported by the conveyor, and thus no transportation loss of the wafer structure occurs (the transportation path does not become long). Consequently, even when the posture of the wafer structure is inverted, an increase in the cycle time can be reduced or prevented.

In such a case, the conveyor preferably includes a rail configured to support, from below, the wafer structure taken out from the wafer storage, and the inversion mechanism is preferably provided as a portion of the rail. Accordingly, the inversion mechanism is provided as a portion of the conveyor by effectively using the rail of the conveyor, and thus the complexity of the structure can be easily reduced or prevented.

In the configuration in which the inversion mechanism is provided as a portion of the rail, the rail preferably includes a pair of rails provided at a predetermined interval, the inversion mechanism is preferably provided as a portion of a first rail of the pair of rails, and a second rail of the pair of rails is preferably configured to be retreated when the posture of the wafer structure is inverted by the inversion mechanism. Accordingly, the inversion mechanism is provided as a portion of the first rail of the pair of rails such that the complexity of the structure can be reduced or prevented as compared with a case in which the inversion mechanism is provided as a portion of both of the pair of rails. Furthermore, the second rail of the pair of rails is retreated when the posture of the wafer structure is inverted by the inversion mechanism such that it is possible to prevent the second rail of the pair of rails from interfering with the wafer structure, and thus the posture of the wafer structure can be easily inverted by the inversion mechanism. Consequently, the posture of the wafer structure can be easily inverted by the inversion mechanism while the complexity of the structure is reduced or prevented.

In such a case, the second rail of the pair of rails is preferably configured to move between an initial position at which the second rail supports the wafer structure from below and a retreated position spaced apart from the wafer structure by rotating about a rotation axis extending along a direction in which the pair of rails extend. Accordingly, with a simple configuration in which the second rail of the pair of rails is simply rotated, the second rail of the pair of rails can be retreated from the initial position to the retreated position. When the second rail of the pair of rails is retreated from the initial position to the retreated position, a portion of the wafer structure that is no longer supported from below by the second rail of the pair of rails may be bent slightly downward. In this regard, the second rail of the pair of rails is rotated such that the second rail of the pair of rails is returned from the retreated position to the initial position, and thus even when the portion of the wafer structure that is no longer supported from below by the second rail of the pair of rails is bent slightly downward, the second rail of the pair of rails can be easily returned to the initial position while the bent portion of the wafer structure is lifted.

In the configuration in which the inversion mechanism is provided as a portion of the rail, the inversion mechanism preferably includes a holder provided as a portion of the rail and configured to hold the wafer structure, and is preferably configured to invert the posture of the wafer structure by rotating the holder while the wafer structure is held by the holder. Accordingly, the holder is provided by effectively using the rail that supports the wafer structure from below, and thus the complexity of the structure is reduced or prevented, and the wafer structure is easily held by the holder.

In the configuration in which the inversion mechanism is provided as a portion of the first rail of the pair of rails, the wafer storage is preferably configured to store the wafer structure including a ring-shaped member surrounding the wafer, and the inversion mechanism preferably includes a clamp unit provided as a portion of the first rail of the pair of rails and configured to clamp an end of the ring-shaped member of the wafer structure in an upward-downward direction, and is preferably configured to invert the posture of the wafer structure by rotating the clamp unit while the end of the ring-shaped member of the wafer structure is clamped by the clamp unit. Accordingly, the clamp unit is provided by effectively using the first rail of the pair of rails that support the wafer structure from below, and thus the complexity of the structure can be reduced or prevented. Furthermore, the end of the ring-shaped member of the wafer structure is clamped by the clamp unit such that the wafer structure can be reliably held, and thus the posture of the wafer structure can be stably inverted.

In the configuration in which the inversion mechanism is provided as a portion of the conveyor, the wafer processing apparatus is preferably configured to switch between a setting in which the posture of the wafer structure is inverted by the inversion mechanism and a setting in which the posture of the wafer structure is not inverted by the inversion mechanism based on information on laser processing of the wafer. Accordingly, depending on the wafer to be processed, it is possible to switch between the laser processing from the circuit surface side of the wafer and the laser processing from the surface side of the wafer opposite to the circuit surface. Consequently, it is possible to improve the degree of freedom in processing the wafer.

A semiconductor chip manufacturing method according to a second aspect of the present disclosure includes performing, using a dicer, dicing to divide, into individual semiconductor chips, a wafer of a wafer structure including the wafer on which a plurality of semiconductor chips have been formed and a sheet member to which the wafer has been attached and supplied from a wafer storage configured to store the wafer structure, and transporting, using a wafer transporter, the wafer structure between the wafer storage and the dicer. The wafer transporter includes an inversion mechanism configured to invert a posture of the wafer structure.

In the semiconductor chip manufacturing method according to the second aspect of the present disclosure, as described above, the wafer transporter includes the inversion mechanism that inverts the posture of the wafer structure. Accordingly, the inversion mechanism is provided by effectively using the wafer transporter, and thus it is not necessary to provide the inversion mechanism separately and independently. Consequently, the complexity of the structure can be reduced or prevented. Furthermore, the wafer structure can be inverted by the inversion mechanism. Consequently, it is possible to provide the semiconductor chip manufacturing method that allows the inversion mechanism to invert the wafer structure while reducing or preventing the complexity of the structure.

A semiconductor chip according to a third aspect of the present disclosure is manufactured by a wafer processing apparatus including a wafer storage configured to store a wafer structure including a wafer on which a plurality of semiconductor chips have been formed and a sheet member to which the wafer has been attached, a dicer configured to perform dicing to divide the wafer of the wafer structure supplied from the wafer storage into individual semiconductor chips, and a wafer transporter configured to transport the wafer structure between the wafer storage and the dicer. The wafer transporter includes an inversion mechanism configured to invert a posture of the wafer structure.

In the semiconductor chip according to the third aspect of the present disclosure, as described above, the wafer transporter includes the inversion mechanism that inverts the posture of the wafer structure. Accordingly, the inversion mechanism is provided by effectively using the wafer transporter, and thus it is not necessary to provide the inversion mechanism separately and independently. Consequently, the complexity of the structure can be reduced or prevented. Furthermore, the wafer structure can be inverted by the inversion mechanism. Consequently, it is possible to provide the semiconductor chip that allows the inversion mechanism to invert the wafer structure while reducing or preventing the complexity of the structure.

According to the present disclosure, as described above, it is possible to invert the wafer structure using the inversion mechanism while reducing or preventing the complexity of the structure.

### BRIEF DESCRIPTION OF THE DRAWINGS

FIG. 1 is a plan view showing a semiconductor wafer processing apparatus including a dicing device and an expanding device according to a first embodiment;

FIG. 2 is a plan view showing a wafer ring structure to be processed in the semiconductor wafer processing apparatus according to the first embodiment;

FIG. 3 is a sectional view taken along the line III-III in FIG. 2;

FIG. 4 is a plan view of the dicing device arranged adjacent to the expanding device according to the first embodiment;

FIG. 5 is a side view showing the dicing device arranged adjacent to the expanding device according to the first embodiment, as viewed from the Y2 direction side;

FIG. 6 is a plan view of the expanding device according to the first embodiment;

FIG. 7 is a side view showing the expanding device according to the first embodiment, as viewed from the Y2 direction side;

FIG. 8 is a side view showing the expanding device according to the first embodiment, as viewed from the X1 direction side;

FIG. 9 is a block diagram showing the control configuration of the semiconductor wafer processing apparatus according to the first embodiment;

FIG. 10 is a flowchart of the first half of a semiconductor chip manufacturing process of the semiconductor wafer processing apparatus according to the first embodiment;

FIG. 11 is a flowchart of the second half of the semiconductor chip manufacturing process of the semiconductor wafer processing apparatus according to the first embodiment;

FIG. 12 is a diagram for illustrating inversion of a wafer according to the first embodiment;

FIG. 13 is a plan view showing a semiconductor wafer processing apparatus including a dicing device and an expanding device according to a second embodiment;

FIG. 14 is a side view showing the semiconductor wafer processing apparatus including the dicing device and the expanding device according to the second embodiment, as viewed from the Y2 direction side;

FIG. 15 is a side view showing the semiconductor wafer processing apparatus including the dicing device and the expanding device according to the second embodiment, as viewed from the X1 direction side;

FIG. 16 is a block diagram showing the control configuration of the semiconductor wafer processing apparatus according to the second embodiment;

FIG. 17 is a flowchart of the first half of a semiconductor chip manufacturing process of the semiconductor wafer processing apparatus according to the second embodiment;

FIG. 18 is a flowchart of the second half of the semiconductor chip manufacturing process of the semiconductor wafer processing apparatus according to the second embodiment;

FIG. 19 is a plan view showing a semiconductor wafer processing apparatus according to a third embodiment;

FIG. 20 is a plan view showing a wafer structure to be processed in the semiconductor wafer processing apparatus according to the third embodiment;

FIG. 21 is a sectional view taken along the line XXI-XXI in FIG. 20;

FIG. 22 is a side view showing a cassette unit and a temporary placement unit according to the third embodiment, as viewed from the Y2 direction side;

FIG. 23 is a diagram (1) for illustrating inversion of a wafer according to the third embodiment;

FIG. 24 is a diagram (2) for illustrating inversion of the wafer according to the third embodiment;

FIG. 25 is a diagram for illustrating imaging of the wafer according to the third embodiment;

FIG. 26 is a plan view showing a semiconductor wafer processing apparatus according to a fourth embodiment;

FIG. 27 is a side view showing an expanding device according to the fourth embodiment, as viewed from the Y2 direction side;

FIG. 28 is a diagram for illustrating inversion of a wafer according to the fourth embodiment;

FIG. 29 is a plan view showing a semiconductor wafer processing apparatus according to a modified example of the fourth embodiment;

FIG. 30 is a diagram for illustrating inversion of a wafer according to the modified example of the fourth embodiment;

FIG. 31 is a plan view showing a semiconductor wafer processing apparatus according to a fifth embodiment;

FIG. 32 is a plan view showing an inversion mechanism and rails according to the fifth embodiment;

FIG. 33 is a diagram (1) for illustrating inversion of a wafer according to the fifth embodiment; and

FIG. 34 is a diagram (2) for illustrating inversion of the wafer according to the fifth embodiment.

Embodiments embodying the present disclosure are hereinafter described on the basis of the drawings.

### First Embodiment

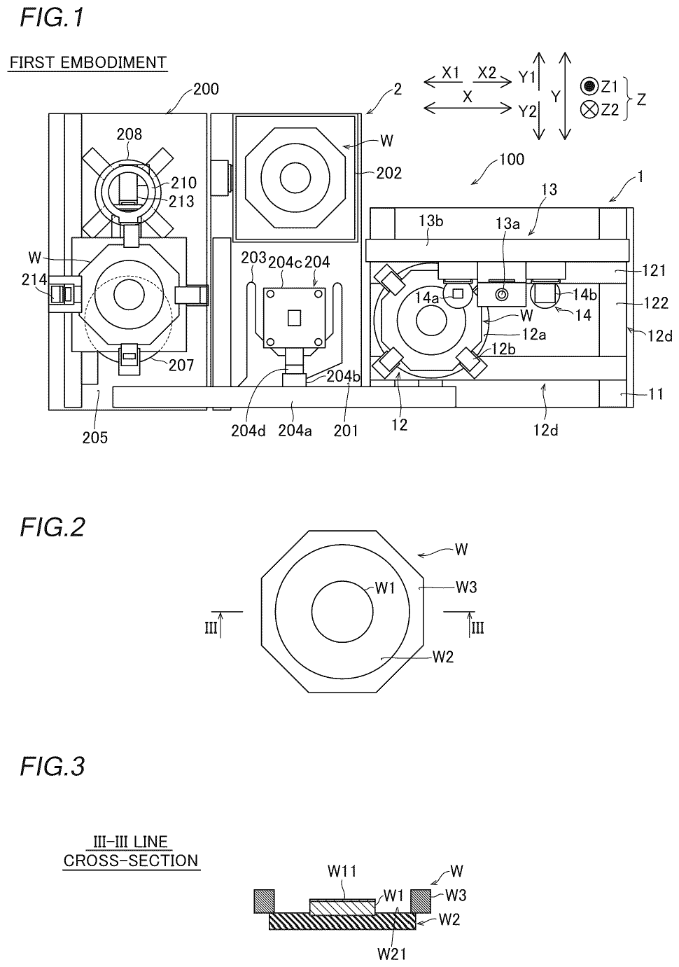

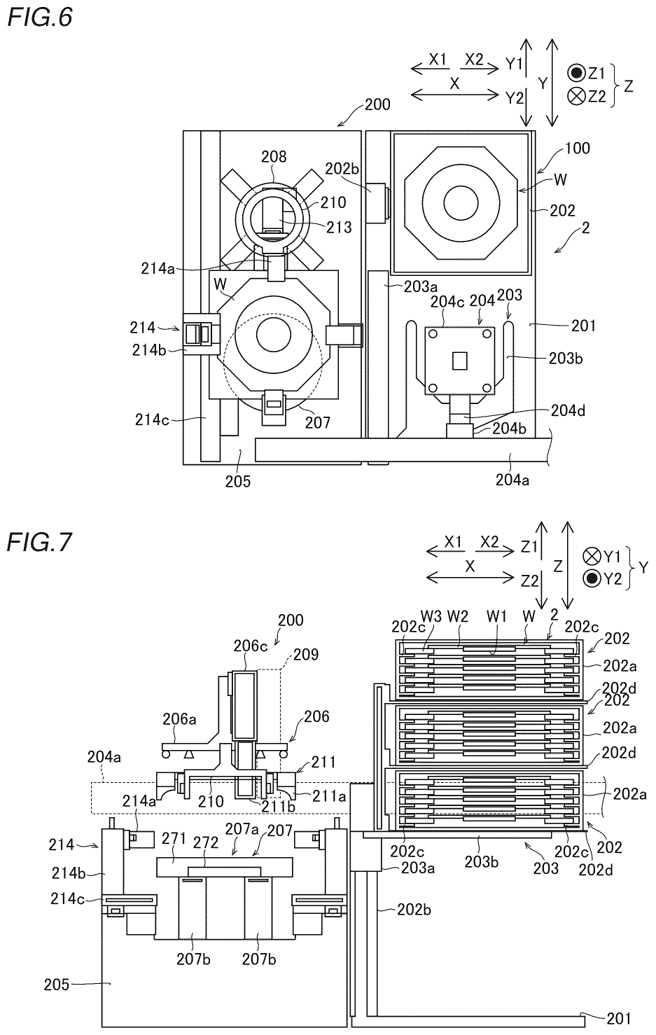

The configuration of a semiconductor wafer processing apparatus 100 according to a first embodiment of the present disclosure is now described with reference to FIGS. 1 to 12. The semiconductor wafer processing apparatus 100 is an example of a “wafer processing apparatus” in the claims.

### Semiconductor Wafer Processing Apparatus

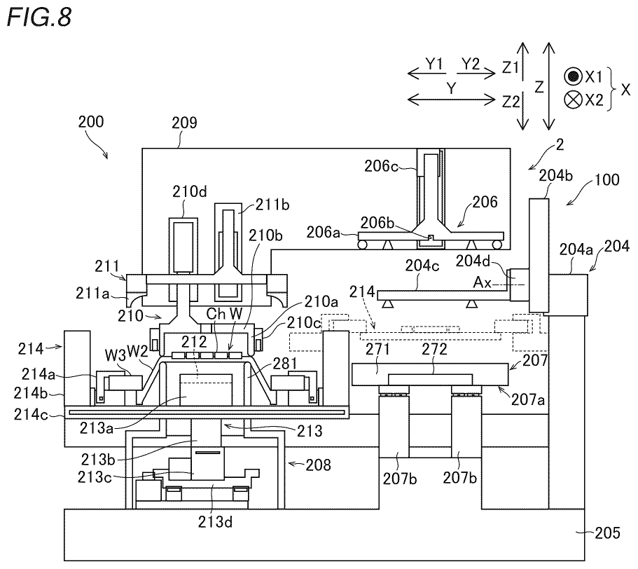

As shown in FIG. 1, the semiconductor wafer processing apparatus 100 is an apparatus that processes a wafer W1 provided on a wafer ring structure W. The semiconductor wafer processing apparatus 100 forms a modified layer in the wafer W1 and divides the wafer W1 along the modified layer to form a plurality of semiconductor chips Ch (see FIG. 8). The wafer ring structure W is an example of a “wafer structure” in the claims.

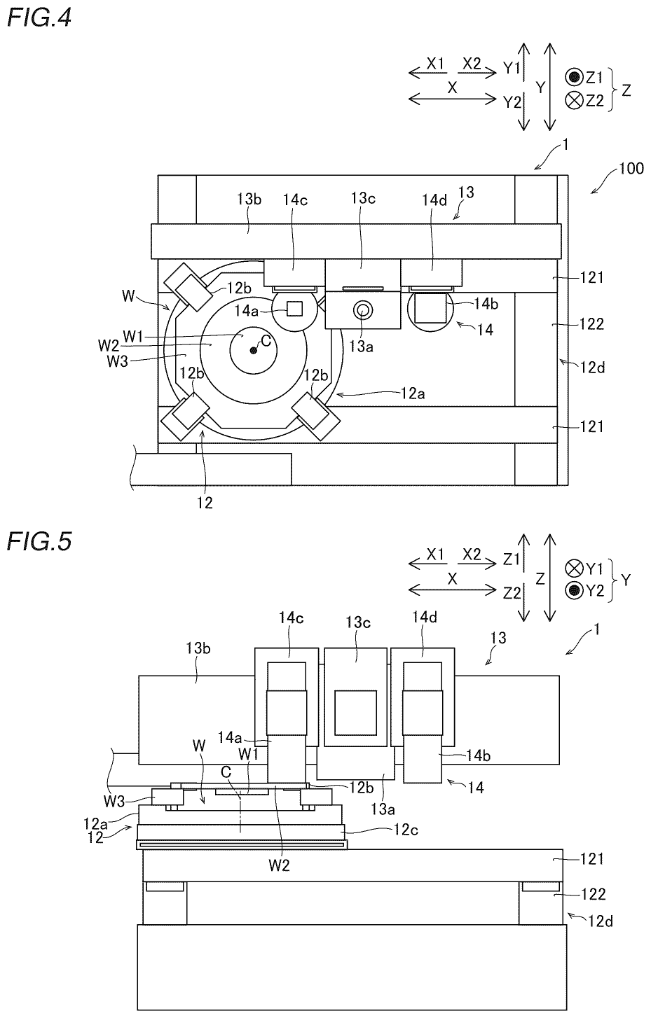

The wafer ring structure W is now described with reference to FIGS. 2 and 3. The wafer ring structure W includes the wafer W1, a sheet member W2, and a ring-shaped member W3.

The wafer W1 is a circular thin plate made of a crystal of a semiconductor material that is used as a material for a semiconductor integrated circuit. Inside the wafer W1, the modified layer is formed by modifying the inside along a dividing line by processing in the semiconductor wafer processing apparatus 100. That is, the wafer W1 is processed so as to be divisible along the dividing line. The sheet member W2 is an elastic adhesive tape. An adhesive layer is provided on the upper surface W21 of the sheet member W2. The wafer W1 is attached to the adhesive layer on the sheet member W2. The ring-shaped member W3 is a ring-shaped metal frame in a plan view. The ring-shaped member W3 is attached to the adhesive layer on the sheet member W2 while surrounding the wafer W1. The wafer W1 includes a circuit layer W11. In the first embodiment, the wafer W1 is arranged on the sheet member W2 such that the circuit layer W11 is arranged on the side opposite to the sheet member W2.

The semiconductor wafer processing apparatus 100 includes a dicing device 1 and an expanding device 2. An upward-downward direction is defined as a Z direction, an upward direction is defined as a Z1 direction, and a downward direction is defined as a Z2 direction. In a horizontal direction perpendicular to the Z direction, a direction in which the dicing device 1 and the expanding device 2 are aligned is defined as an X direction, a direction from the dicing device 1 toward the expanding device 2 in the X direction is defined as an X1 direction, and a direction from the expanding device 2 toward the dicing device 1 in the X direction is defined as an X2 direction. A direction perpendicular to the X direction in the horizontal direction is defined as a Y direction, one direction in the Y direction is defined as a Y1 direction, and the other direction in the Y direction is defined as a Y2 direction. The dicing device 1 is an example of a “dicer” in the claims.

### Dicing Device

As shown in FIGS. 1, 4, and 5, the dicing device 1 performs dicing on the wafer W1, which is supplied from a cassette unit 202 (described below) and on which a plurality of semiconductor chips Ch have been formed, in order to divide the wafer W1 into the plurality of semiconductor chips Ch. The dicing device 1 emits a laser having a wavelength transmissive to the wafer W1 along the dividing line (street) to form the modified layer. The modified layer refers to a crack, a void, or the like formed inside the wafer W1 by the laser. A method for forming the modified layer in the wafer W1 in this manner is called dicing.

Specifically, the dicing device 1 includes a base 11, a chuck table unit 12, a laser 13, and an imager 14.

The base 11 is a base on which the chuck table unit 12 is installed. The base 11

has a rectangular shape in the plan view.

### Chuck Table Unit

The chuck table unit 12 includes a suction unit 12a, clamps 12b, a rotation mechanism 12c, and a table movement mechanism 12d. The suction unit 12a suctions the wafer ring structure W on the upper surface of the suction unit 12a on the Z1 direction side. The suction unit 12a is a table including a suction hole, a suction pipe line, etc. to suction the lower surface of the ring-shaped member W3 of the wafer ring structure W on the Z2 direction side. The suction unit 12a is supported by the table movement mechanism 12d via the rotation mechanism 12c. The clamps 12b are provided at an upper end of the suction unit 12a. The clamps 12b hold the wafer ring structure W suctioned by the suction unit 12a. The clamps 12b hold the ring-shaped member W3 of the wafer ring structure W suctioned by the suction unit 12a from the Z1 direction side. In this manner, the wafer ring structure W is held by the suction unit 12a and the clamps 12b.

The rotation mechanism 12c rotates the suction unit 12a in a circumferential direction around a rotation center axis C extending parallel to the Z direction. The rotation mechanism 12c is attached to an upper end of the table movement mechanism 12d. The table movement mechanism 12d moves the wafer ring structure W in the X and Y directions. The table movement mechanism 12d includes an X-direction movement mechanism 121 and a Y-direction movement mechanism 122. The X-direction movement mechanism 121 moves the rotation mechanism 12c in the X1 direction or the X2 direction. The X-direction movement mechanism 121 includes a linear conveyor module, or a ball screw and a drive including a motor with an encoder, for example. The Y-direction movement mechanism 122 moves the rotation mechanism 12c in the Y1 direction or the Y2 direction. The Y-direction movement mechanism 122 includes a linear conveyor module, or a ball screw and a drive including a motor with an encoder, for example.

### Laser

The laser 13 emits a laser beam to the wafer W1 of the wafer ring structure W held by the chuck table unit 12. The laser 13 is arranged on the Z1 direction side of the chuck table unit 12. The laser 13 includes a laser irradiator 13a, a mounting member 13b, and a Z-direction movement mechanism 13c. The laser irradiator 13a emits a pulsed laser beam. The mounting member 13b is a frame to which the laser 13 and the imager 14 are mounted. The Z-direction movement mechanism 13c moves the laser 13 in the Z1 direction or the Z2 direction. The Z-direction movement mechanism 13c includes a linear conveyor module, or a ball screw and a drive including a motor with an encoder, for example. The laser irradiator 13a may be a laser irradiator that oscillates a continuous wave laser beam other than a pulsed laser beam as the laser beam as long as a modified layer can be formed by multiphoton absorption.

### Imager

The imager 14 images the wafer W1 of the wafer ring structure W held by the chuck table unit 12. The imager 14 is arranged on the Z1 direction side of the chuck table unit 12. The imager 14 includes a high-resolution camera 14a, a wide-angle camera 14b, a Z-direction movement mechanism 14c, and a Z-direction movement mechanism 14d.

The high-resolution camera 14a and the wide-angle camera 14b are near-infrared imaging cameras. The high-resolution camera 14a has a narrower viewing angle than the wide-angle camera 14b. The high-resolution camera 14a has a higher resolution than the wide-angle camera 14b. The wide-angle camera 14b has a wider viewing angle than the high-resolution camera 14a. The wide-angle camera 14b has a lower resolution than the high-resolution camera 14a. The high-resolution camera 14a is arranged on the X1 direction side of the laser irradiator 13a. The wide-angle camera 14b is arranged on the X2 direction side of the laser irradiator 13a. Thus, the high-resolution camera 14a, the laser irradiator 13a, and the wide-angle camera 14b are arranged adjacent to each other in this order from the X1 direction side toward the X2 direction side.

The Z-direction movement mechanism 14c moves the high-resolution camera 14a in the Z1 direction or the Z2 direction. The Z-direction movement mechanism 14c includes a linear conveyor module, or a ball screw and a drive including a motor with an encoder, for example. The Z-direction movement mechanism 14d moves the wide-angle camera 14b in the Z1 direction or the Z2 direction. The Z-direction movement mechanism 14d includes a linear conveyor module, or a ball screw and a drive including a motor with an encoder, for example.

### Expanding Device

As shown in FIGS. 1, 6, and 7, the expanding device 2 divides the wafer W1 to form the plurality of semiconductor chips Ch (see FIG. 8). The expanding device 2 forms a sufficient gap between the plurality of semiconductor chips Ch. A modified layer is formed in the wafer W1 by emitting a laser having a wavelength transmissive to the wafer W1 along the dividing line (street) in the dicing device 1. In the expanding device 2, the plurality of semiconductor chips Ch are formed by dividing the wafer W1 along the modified layer formed in advance in the dicing device 1.

Therefore, in the expanding device 2, the wafer W1 is divided along the modified layer by expanding the sheet member W2. Furthermore, in the expanding device 2, the gap between the plurality of semiconductor chips Ch formed by division is widened by expanding the sheet member W2.

The expanding device 2 includes an expanding main body 200, a base 201, a cassette unit 202, a lift-up hand unit 203, and a suction hand unit 204. The expanding main body 200 expands the sheet member W2 to which the wafer W1 (having the modified layer formed thereon) that has been diced by the dicing device 1 has been attached. The expanding main body 200 includes a base 205, a cool air supplier 206, a cooling unit 207, an expander 208, a base 209, an expansion maintaining member 210, a heat shrinker 211, an ultraviolet irradiator 212, a squeegee unit 213, and a clamp unit 214. The expanding main body 200 is an example of an “expander” in the claims. The cassette unit 202 is an example of a “wafer storage” in the claims. The lift-up hand unit 203 and the suction hand unit 204 are examples of a “wafer transporter” in the claims. The lift-up hand unit 203 is an example of an “taking-out unit” in the claims. The suction hand unit 204 is an example of a “suction unit” or a “transport mechanism” in the claims. The cool air supplier 206 is an example of a “cooler” in the claims.

### Base

The base 201 is a base on which the cassette unit 202 and the lift-up hand unit 203 are installed. The base 201 has a rectangular shape in the plan view.

### Cassette Unit

The cassette unit 202 can accommodate a plurality of wafer ring structures W. In the first embodiment, the wafer ring structure W is stored in the cassette unit 202 such that the sheet member W2 is arranged on the upper side, the wafer W1 is arranged on the lower side, and the circuit layer W11 is arranged on the lower side. The cassette unit 202 includes wafer cassettes 202a, a Z-direction movement mechanism 202b, and pairs of placement portions 202c.

A plurality of (three) wafer cassettes 202a are arranged in the Z direction. Each of the wafer cassettes 202a has an accommodation space capable of accommodating a plurality of (five) wafer ring structures W. The wafer ring structure W is manually supplied and placed in the wafer cassette 202a. The wafer cassette 202a may accommodate one to four wafer ring structures W, or may accommodate six or more wafer ring structures W. Furthermore, one, two, or four or more wafer cassettes 202a may be arranged in the Z direction.

The Z-direction movement mechanism 202b moves the wafer cassettes 202a in the Z1 direction or the Z2 direction. The Z-direction movement mechanism 202b includes a linear conveyor module, or a ball screw and a drive including a motor with an encoder, for example. The Z-direction movement mechanism 202b also includes mounting tables 202d that support the wafer cassettes 202a from below. A plurality of (three) mounting tables 202d are arranged according to the positions of the plurality of wafer cassettes 202a.

A plurality of (five) pairs of placement portions 202c are arranged inside the wafer cassette 202a. The ring-shaped member W3 of the wafer ring structure W is placed on the pair of placement portions 202c from the Z1 direction side. One of the pair of placement portions 202c protrudes in the X2 direction from the inner surface of the wafer cassette 202a on the X1 direction side. The other of the pair of placement portions 202c protrudes in the X1 direction from the inner surface of the wafer cassette 202a on the X2 direction side.

### Lift-Up Hand Unit

The lift-up hand unit 203 can take out the wafer ring structure W from the cassette unit 202. Furthermore, the lift-up hand unit 203 can take the wafer ring structure W into the cassette unit 202.

Specifically, the lift-up hand unit 203 includes a Y-direction movement mechanism 203a and a lift-up hand 203b. The Y-direction movement mechanism 203a includes a linear conveyor module, or a ball screw and a drive including a motor with an encoder, for example. The lift-up hand 203b supports the ring-shaped member W3 of the wafer ring structure W from the Z2 direction side.

### Suction Hand Unit

The suction hand unit 204 suctions the ring-shaped member W3 of the wafer ring structure W from the Z1 direction side.

Specifically, the suction hand unit 204 includes an X-direction movement mechanism 204a, a Z-direction movement mechanism 204b, and a suction hand 204c. The X-direction movement mechanism 204a moves the suction hand 204c in the X direction. The Z-direction movement mechanism 204b moves the suction hand 204c in the Z direction. Each of the X-direction movement mechanism 204a and the Z-direction movement mechanism 204b includes a linear conveyor module, or a ball screw and a drive including a motor with an encoder, for example. The suction hand 204c suctions and supports the ring-shaped member W3 of the wafer ring structure W from the Z1 direction side. The suction hand 204c supports the ring-shaped member W3 of the wafer ring structure W by generating a negative pressure. The suction hand 204c includes a suction hole or the like to suction the wafer ring structure W by the negative pressure. The wafer transporter includes the lift-up hand unit 203 and the suction hand unit 204, and transports the wafer ring structure W between the cassette unit 202, the dicing device 1, and the expanding main body 200. In the first embodiment, the wafer transporter includes the lift-up hand unit 203 to take out the wafer ring structure W from the cassette unit 202, and the suction hand unit 204 to transport the taken-out wafer ring structure W.

### Base

As shown in FIGS. 7 and 8, the base 205 is a base on which the expander 208, the cooling unit 207, the ultraviolet irradiator 212, and the squeegee unit 213 are installed. The base 205 has a rectangular shape in the plan view. In FIG. 8, the clamp unit 214 arranged on the Z1 direction side of the cooling unit 207 is indicated by dotted lines.

### Cool Air Supplier

The cool air supplier 206 cools the sheet member W2 when the sheet member W2 is expanded. The cool air supplier 206 supplies cool air to the sheet member W2 from the Z1 direction side when the sheet member W2 is expanded by the expander 208.

Specifically, the cool air supplier 206 includes a supplier main body 206a, a cool air supply port 206b, and a movement mechanism 206c. The cool air supply port 206b allows cool air supplied from a cool air supply device to flow out therethrough. The cool air supply port 206b is provided at an end of the supplier main body 206a on the Z2 direction side. The cool air supply port 206b is arranged in a central portion of the end of the supplier main body 206a on the Z2 direction side. The movement mechanism 206c includes a linear conveyor module, or a ball screw and a drive including a motor with an encoder, for example.

The cool air supply device is a device that generates cool air. The cool air supply device supplies air cooled by a heat pump, for example. Such a cool air supply device is installed on the base 205. The cool air supplier 206 and the cool air supply device are connected to each other by a hose (not shown).

### Cooling Unit

The cooling unit 207 cools the sheet member W2 from the Z2 direction side.

Specifically, the cooling unit 207 includes a cooling member 207a including a cooling body 271 and a Peltier element 272, and a Z-direction movement mechanism 207b. The cooling body 271 is made of a member having a large heat capacity and a high thermal conductivity. The cooling body 271 is made of metal such as aluminum. The Peltier element 272 cools the cooling body 271. The cooling body 271 is not limited to aluminum, and may be another member having a large heat capacity and a high thermal conductivity. The Z-direction movement mechanism 207b is a cylinder.

The cooling unit 207 is movable in the Z1 direction or the Z2 direction by the Z-direction movement mechanism 207b. Thus, the cooling unit 207 is movable to a position contacting the sheet member W2 and a position spaced apart from the sheet member W2.

### Expander

The expander 208 expands the sheet member W2 of the wafer ring structure W to divide the wafer W1 along the dividing line.

Specifically, the expander 208 includes an expanding ring 281. The expanding ring 281 expands the sheet member W2 by supporting the sheet member W2 from the Z2 direction side. The expanding ring 281 has a ring shape in the plan view. The structure of the expanding ring 281 is described in detail below.

### Base

The base 209 is a base material on which the cool air supplier 206, the expansion maintaining member 210, and the heat shrinker 211 are installed.

### Expansion Maintaining Member

As shown in FIGS. 7 and 8, the expansion maintaining member 210 holds down the sheet member W2 from the Z1 direction side such that the sheet member W2 in the vicinity of the wafer W1 does not shrink due to heating by a heating ring 211a.

Specifically, the expansion maintaining member 210 includes a pressing ring 210a, a lid 210b, and an intake 210c. The pressing ring 210a has a ring shape in the plan view. The lid 210b is provided on the pressing ring 210a to close an opening of the pressing ring 210a. The intake 210c is an intake ring having a ring shape in the plan view. A plurality of intake ports are formed in the lower surface of the intake 210c on the Z2 direction side. The pressing ring 210a is moved in the Z direction by a Z-direction movement mechanism 210d. That is, the Z-direction movement mechanism 210d moves the pressing ring 210a to a position at which the sheet member W2 is held down and a position away from the sheet member W2. The Z-direction movement mechanism 210d includes a linear conveyor module, or a ball screw and a drive including a motor with an encoder, for example.

### Heat Shrinker

The heat shrinker 211 shrinks the sheet member W2 expanded by the expander 208 by heating while maintaining the gap between the plurality of semiconductor chips Ch.

The heat shrinker 211 includes the heating ring 211a and a Z-direction movement mechanism 211b. The heating ring 211a has a ring shape in the plan view. The heating ring 211a includes a sheathed heater that heats the sheet member W2. The Z-direction movement mechanism 211b moves the heating ring 211a in the Z direction. The Z-direction movement mechanism 211b includes a linear conveyor module, or a ball screw and a drive including a motor with an encoder, for example.

### Ultraviolet Irradiator

The ultraviolet irradiator 212 emits ultraviolet rays to the sheet member W2 in order to reduce the adhesive strength of the adhesive layer of the sheet member W2. Specifically, the ultraviolet irradiator 212 includes an ultraviolet illuminator. The ultraviolet irradiator 212 is arranged at an end of a press 213a of the squeegee unit 213, which is described below, on the Z1 direction side. The ultraviolet irradiator 212 emits the ultraviolet rays to the sheet member W2 while moving together with the squeegee unit 213.

### Squeegee Unit

The squeegee unit 213 further divides the wafer W1 along the modified layer by locally pressing the wafer W1 from the Z2 direction side after the sheet member W2 is expanded. Specifically, the squeegee unit 213 includes the press 213a, a Z-direction movement mechanism 213b, an X-direction movement mechanism 213c, and a rotation mechanism 213d.

The press 213a generates a bending stress in the wafer W1 to divide the wafer W1 along the modified layer by being moved by the rotation mechanism 213d and the X-direction movement mechanism 213c while pressing the wafer W1 from the Z2 direction side via the sheet member W2. The press 213a presses the wafer W1 via the sheet member W2 by being raised to a raised position on the Z1 direction side by the Z-direction movement mechanism 213b. When the press 213a is lowered to a lowered position on the Z2 direction side by the Z-direction movement mechanism 213b, the wafer W1 is no longer pressed. The press 213a is a squeegee.

The press 213a is attached to an end of the Z-direction movement mechanism 213b on the Z1 direction side. The Z-direction movement mechanism 213b linearly moves the press 213a in the Z1 direction or the Z2 direction. The Z-direction movement mechanism 213b is a cylinder, for example. The Z-direction movement mechanism 213b is attached to an end of the X-direction movement mechanism 213c on the Z1 direction side.

The X-direction movement mechanism 213c is attached to an end of the rotation mechanism 213d on the Z1 direction side. The X-direction movement mechanism 213c linearly moves the press 213a in one direction. The X-direction movement mechanism 213c includes a linear conveyor module, or a ball screw and a drive including a motor with an encoder, for example.

In the squeegee unit 213, the press 213a is raised to the raised position by the Z-direction movement mechanism 213b. In the squeegee unit 213, the press 213a is moved in the Y direction by the X-direction movement mechanism 213c while locally pressing the wafer W1 from the Z2 direction side via the sheet member W2 such that the wafer W1 is divided. In the squeegee unit 213, the press 213a is lowered to the lowered position by the Z-direction movement mechanism 213b. In the squeegee unit 213, after the press 213a finishes moving in the Y direction, the press 213a is rotated 90 degrees by the rotation mechanism 213d.

In the squeegee unit 213, the press 213a is raised to the raised position by the Z-direction movement mechanism 213b. In the squeegee unit 213, after the press 213a is rotated 90 degrees, the press 213a is moved in the X direction by the X-direction movement mechanism 213c while locally pressing the wafer W1 from the Z2 direction side via the sheet member W2 such that the wafer W1 is divided.

### Clamp Unit

The clamp unit 214 holds the ring-shaped member W3 of the wafer ring structure W. Specifically, the clamp unit 214 includes a gripper 214a, a Z-direction movement mechanism 214b, and a Y-direction movement mechanism 214c. The gripper 214a supports the ring-shaped member W3 from the Z2 direction side and holds down the ring-shaped member W3 from the Z1 direction side. Thus, the ring-shaped member W3 is held by the gripper 214a. The gripper 214a is attached to the Z-direction movement mechanism 214b.

The Z-direction movement mechanism 214b moves the clamp unit 214 in the Z direction. Specifically, the Z-direction movement mechanism 214b moves the gripper 214a in the Z1 direction or the Z2 direction. The Z-direction movement mechanism 214b includes a linear conveyor module, or a ball screw and a drive including a motor with an encoder, for example. The Z-direction movement mechanism 214b is attached to the Y-direction movement mechanism 214c. The Y-direction movement mechanism 214c moves the Z-direction movement mechanism 214b in the Y1 direction or the Y2 direction. The Y-direction movement mechanism 214c includes a linear conveyor module, or a ball screw and a drive including a motor with an encoder, for example.

### Control Configuration of Semiconductor Wafer Processing Apparatus

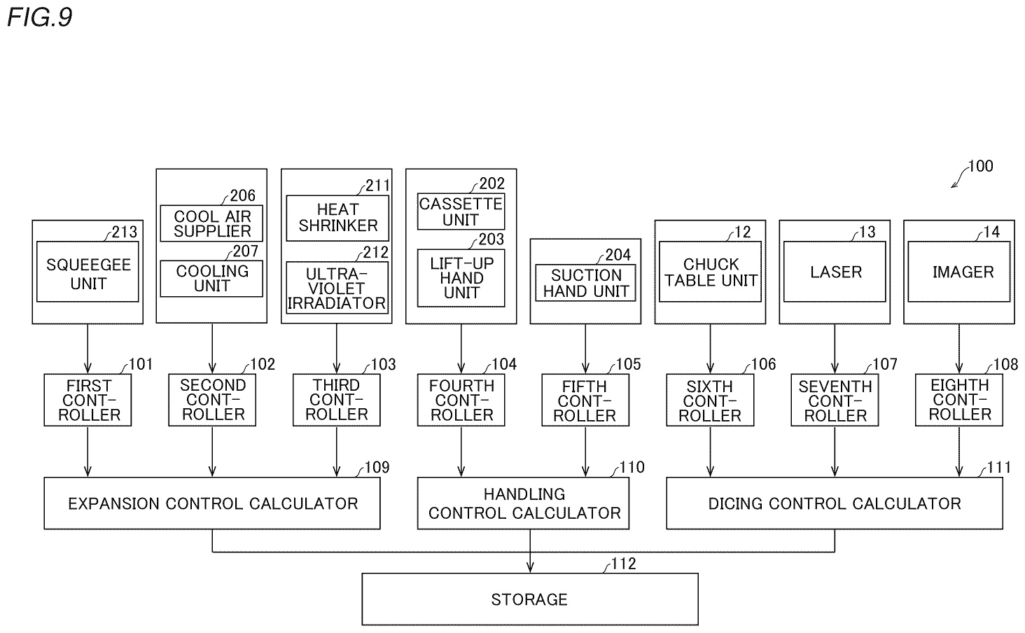

As shown in FIG. 9, the semiconductor wafer processing apparatus 100 includes a first controller 101, a second controller 102, a third controller 103, a fourth controller 104, a fifth controller 105, a sixth controller 106, a seventh controller 107, an eighth controller 108, an expansion control calculator 109, a handling control calculator 110, and a dicing control calculator 111.

The first controller 101 controls the squeegee unit 213. The first controller 101 includes a central processing unit (CPU) and a storage including a read-only memory (ROM) and a random access memory (RAM), for example. The first controller 101 may include, as a storage, a hard disk drive (HDD) that retains stored information even after the voltage is cut off, for example. The HDD may be provided in common for the first controller 101, the second controller 102, the third controller 103, the fourth controller 104, the fifth controller 105, the sixth controller 106, the seventh controller 107, and the eighth controller 108.

The second controller 102 controls the cool air supplier 206 and the cooling unit 207. The second controller 102 includes a CPU and a storage including a ROM and a RAM, for example. The third controller 103 controls the heat shrinker 211 and the ultraviolet irradiator 212. The third controller 103 includes a CPU and a storage including a ROM and a RAM, for example. The second controller 102 and the third controller 103 may include, as a storage, an HDD that retains stored information even after the voltage is cut off.

The fourth controller 104 controls the cassette unit 202 and the lift-up hand unit 203. The fourth controller 104 includes a CPU and a storage including a ROM and a RAM, for example. The fifth controller 105 controls the suction hand unit 204. The fifth controller 105 includes a CPU and a storage including a ROM and a RAM, for example. The fourth controller 104 and the fifth controller 105 may include, as a storage, an HDD that retains stored information even after the voltage is cut off, for example.

The sixth controller 106 controls the chuck table unit 12. The sixth controller 106 includes a CPU and a storage including a ROM and a RAM, for example. The seventh controller 107 controls the laser 13. The seventh controller 107 includes a CPU and a storage including a ROM and a RAM, for example. The eighth controller 108 controls the imager 14. The eighth controller 108 includes a CPU and a storage including a ROM and a RAM, for example. The sixth controller 106, the seventh controller 107, and the eighth controller 108 may include, as a storage, an HDD that retains stored information even after the voltage is cut off, for example.

The expansion control calculator 109 performs calculations regarding a process to expand the sheet member W2 based on the processing results of the first controller 101, the second controller 102, and the third controller 103. The expansion control calculator 109 includes a CPU and a storage including a ROM and a RAM, for example.

The handling control calculator 110 performs calculations regarding a process to move the wafer ring structure W based on the processing results of the fourth controller 104 and the fifth controller 105. The handling control calculator 110 includes a CPU and a storage including a ROM and a RAM, for example.

The dicing control calculator 111 performs calculations regarding a process to dice the wafer W1 based on the processing results of the sixth controller 106, the seventh controller 107, and the eighth controller 108. The dicing control calculator 111 includes a CPU and a storage including a ROM and a RAM, for example.

The storage 112 stores programs for operating the dicing device 1 and the expanding device 2. The storage 112 includes a ROM, a RAM, and an HDD, for example.

### Semiconductor Chip Manufacturing Process

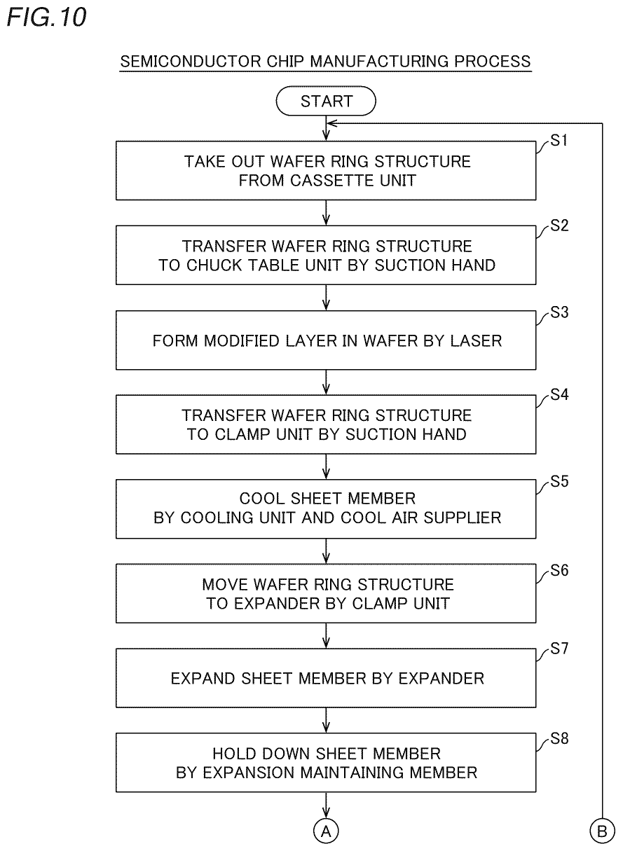

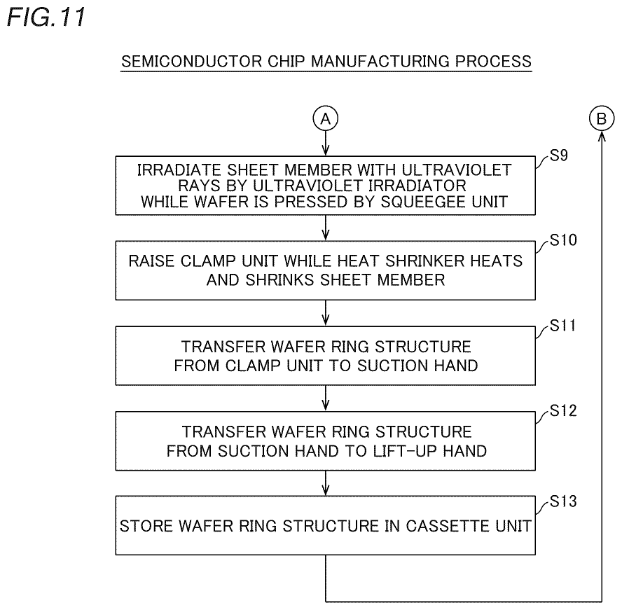

The overall operation of the semiconductor wafer processing apparatus 100 is described below with reference to FIGS. 10 and 11.

In step S1, the wafer ring structure W is taken out from the cassette unit 202. That is, after the wafer ring structure W stored in the cassette unit 202 is supported by the lift-up hand 203b, the lift-up hand 203b is moved in the Y1 direction by the Y-direction movement mechanism 203a such that the wafer ring structure W is taken out from the cassette unit 202. In step S2, the wafer ring structure W is transferred to the chuck table unit 12 of the dicing device 1 by the suction hand 204c. That is, the wafer ring structure W taken out from the cassette unit 202 is moved in the X2 direction by the X-direction movement mechanism 204a while being suctioned by the suction hand 204c. The wafer ring structure W that has been moved in the X2 direction is transferred from the suction hand 204c to the chuck table unit 12 and then held by the chuck table unit 12.

In step S3, a modified layer is formed in the wafer W1 by the laser 13. In step S4, the wafer ring structure W including the wafer W1 in which the modified layer has been formed is transferred to the clamp unit 214 by the suction hand 204c. In step S5, the sheet member W2 is cooled by the cool air supplier 206 and the cooling unit 207. That is, the wafer ring structure W held by the clamp unit 214 is moved (lowered) in the Z2 direction by the Z-direction movement mechanism 214b to contact the cooling unit 207, and the cool air supplier 206 supplies cool air from the Z1 direction side to cool the sheet member W2.

In step S6, the wafer ring structure W is moved to the expander 208 by the clamp unit 214. That is, the wafer ring structure W with the cooled sheet member W2 is moved in the Y1 direction by the Y-direction movement mechanism 214c while being held by the clamp unit 214. In step S7, the sheet member W2 is expanded by the expander 208. That is, the wafer ring structure W is moved in the Z2 direction by the Z-direction movement mechanism 214b while being held by the clamp unit 214. Then, the sheet member W2 contacts the expanding ring 281 and is expanded by being pulled by the expanding ring 281. Thus, the wafer W1 is divided along the dividing line (modified layer).

In step S8, the expanded sheet member W2 is held down from the Z1 direction side by the expansion maintaining member 210. That is, the pressing ring 210a is moved (lowered) in the Z2 direction by the Z-direction movement mechanism 210d until it contacts the sheet member W2. Then, the process advances from a point A in FIG. 10 through a point A in FIG. 11 to step S9.

As shown in FIG. 11, in step S9, after the sheet member W2 is held down by the expansion maintaining member 210, the sheet member W2 is irradiated with ultraviolet rays by the ultraviolet irradiator 212 while the wafer W1 is pressed by the squeegee unit 213. Thus, the wafer W1 is further divided by the squeegee unit 213. In addition, the adhesive strength of the sheet member W2 is reduced by the ultraviolet rays emitted from the ultraviolet irradiator 212.

In step S10, while the heat shrinker 211 heats and shrinks the sheet member W2, the clamp unit 214 is raised. At this time, the intake 210c takes in air in the vicinity of the heated sheet member W2. In step S11, the wafer ring structure W is transferred from the clamp unit 214 to the suction hand 204c. That is, the wafer ring structure W is moved in the Y2 direction by the Y-direction movement mechanism 214c while being held by the clamp unit 214. Then, the wafer ring structure W is suctioned by the suction hand 204c after the holding by the clamp unit 214 is released on the Z1 direction side of the cooling unit 207.

In step S12, the wafer ring structure W is transferred to the lift-up hand 203b by the suction hand 204c. In step S13, the wafer ring structure W is stored in the cassette unit 202. That is, the wafer ring structure W supported by the lift-up hand 203b is moved in the Y1 direction by the Y-direction movement mechanism 203a to be stored in the cassette unit 202. Thus, the process performed on one wafer ring structure W is terminated. Then, the process returns from a point B in FIG. 11 through a point B in FIG. 10 to step S1.

### Inversion Mechanism

In the first embodiment, as shown in FIGS. 1, 6, and 8, the suction hand unit 204 includes an inversion mechanism 204d to invert the posture of the wafer ring structure W.

A manufacturing method for the semiconductor chip Ch by the semiconductor wafer processing apparatus 100 includes a step of dicing, using the dicing device 1, the wafer W1 of the wafer ring structure W supplied from the cassette unit 202 that stores the wafer ring structure W including the wafer W1 on which the plurality of semiconductor chips Ch have been formed and the sheet member W2 to which the wafer W1 has been attached in order to divide the wafer W1 into the individual semiconductor chips Ch, and a step of transporting the wafer ring structure W between the cassette unit 202 and the dicing device 1 using the lift-up hand unit 203 and the suction hand unit 204, and the suction hand unit 204 includes the inversion mechanism 204d to invert the posture of the wafer ring structure W.

The semiconductor chip Ch manufactured by the semiconductor wafer processing apparatus 100 is manufactured by the semiconductor wafer processing apparatus 100 including the cassette unit 202 to store the wafer ring structure W including the wafer W1 on which the plurality of semiconductor chips Ch have been formed and the sheet member W2 to which the wafer W1 has been attached, the dicing device 1 to dice the wafer W1 of the wafer ring structure W supplied from the cassette unit 202 to divide the wafer W1 into the individual semiconductor chips Ch, and the lift-up hand unit 203 and the suction hand unit 204, which includes the inversion mechanism 204d to invert the posture of the wafer ring structure W, to transport the wafer ring structure W between the cassette unit 202 and the dicing device 1.

In the first embodiment, the inversion mechanism 204d is provided in the suction hand unit 204. In the first embodiment, the inversion mechanism 204d rotates the suction hand 204c of the suction hand unit 204 that is suctioning the wafer ring structure W about a rotation axis Ax extending in the horizontal direction (Y direction) to invert the posture of the wafer ring structure W. The inversion mechanism 204d includes a motor and a rotation shaft rotated by the motor. The rotation shaft of the inversion mechanism 204d is connected to the suction hand 204c so as to be able to rotate the suction hand 204c about the rotation axis Ax.

In the first embodiment, the suction hand unit 204 supplies the wafer ring structure W to the dicing device 1 without inverting the wafer ring structure W using the inversion mechanism 204d, and inverts the wafer ring structure W using the inversion mechanism 204d and supplies it to the expanding main body 200. Specifically, the suction hand unit 204 supplies the wafer ring structure W, in which the sheet member W2 is arranged on the upper side and the wafer W1 is arranged on the lower side, to the dicing device 1, and supplies the wafer ring structure W, in which the sheet member W2 is arranged on the lower side and the wafer W1 is arranged on the upper side, to the expanding main body 200 by inverting the wafer ring structure W using the inversion mechanism 204d.

In the first embodiment, the suction hand unit 204 inverts the wafer ring structure W using the inversion mechanism 204d and delivers it to the cool air supplier 206. Specifically, the suction hand unit 204 inverts the wafer ring structure W using the inversion mechanism 204d to deliver the wafer ring structure W, in which the sheet member W2 is arranged on the lower side and the wafer W1 is arranged on the upper side, to the cool air supplier 206. The cool air supplier 206 generates a negative pressure to suction the wafer ring structure W and receives the wafer ring structure W from the suction hand unit 204. The cool air supplier 206 includes a suction hole or the like to suction the wafer ring structure W by the negative pressure.

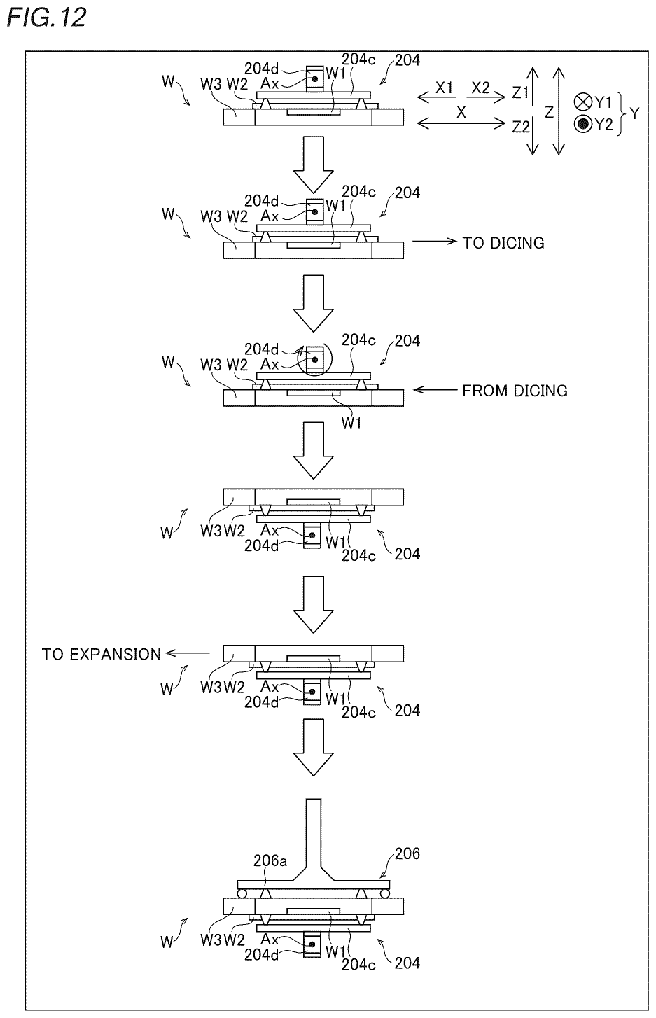

The inversion of the wafer ring structure W is described with reference to FIG. 12. The operation of the dicing device 1 is controlled by the dicing control calculator 111. The operations of the lift-up hand unit 203 and the suction hand unit 204 are controlled by the handling control calculator 110. The operation of the expanding main body 200 is controlled by the expansion control calculator 109.

First, the wafer ring structure W in which the sheet member W2 is arranged on the upper side and the wafer W1 is arranged on the lower side (hereinafter referred to as the wafer ring structure W in the first state) is taken out from the cassette unit 202 by the lift-up hand unit 203. Then, as shown in FIG. 12, the wafer ring structure W in the first state is delivered from the lift-up hand unit 203 to the suction hand unit 204. Then, the wafer ring structure W in the first state is supplied to the dicing device 1 by the suction hand unit 204. In the dicing device 1, the wafer ring structure W in the first state is received by the chuck table unit 12.

Then, the modified layer is formed by emitting a laser beam to the wafer ring structure W in the first state by the laser 13. At this time, the laser beam is emitted to the wafer W1 through the sheet member W2 from the side opposite to the circuit layer W11 by the laser 13. When the laser beam is emitted from the circuit layer W11 side on which the street is formed, the width of the laser beam may not fit within the width of the street when the width of the street is narrow. However, the laser beam is emitted to the wafer W1 through the sheet member W2 from the side opposite to the circuit layer W11 by the laser 13 such that it is possible to prevent the width of the laser beam from not fitting within the width of the street. Thus, the wafer W1 is supplied to the dicing device 1 in a posture suitable for dicing.

Then, after dicing, the wafer ring structure W in the first state is delivered from the chuck table unit 12 to the suction hand unit 204. Then, during transportation from the dicing device 1 to the expanding main body 200, the wafer ring structure W in the first state is inverted by the inversion mechanism 204d. Then, the wafer ring structure W in which the sheet member W2 is arranged on the lower side and the wafer W1 is arranged on the upper side (hereinafter referred to as the wafer ring structure W in the second state) is supplied to the expanding main body 200 by the suction hand unit 204. In the expanding main body 200, the wafer ring structure W in the second state is delivered from the suction hand unit 204 to the cool air supplier 206. At this time, the upper surface of the ring-shaped member W3 of the wafer ring structure W in the second state is suctioned by the cool air supplier 206. Then, the wafer ring structure W in the second state is delivered from the cool air supplier 206 to the clamp unit 214.

Then, the wafer ring structure W in the second state is cooled by the cool air supplier 206 and the cooling unit 207, is expanded by the expander 208, is irradiated with ultraviolet rays by the ultraviolet irradiator 212, is squeegee-broken by the squeegee unit 213, and is heat-shrunk by the heat shrinker 211. During the expansion by the expander 208, the wafer ring structure W in the second state, in which the sheet member W2 is arranged on the lower side and the wafer W1 is arranged on the upper side, is expanded. Thus, the wafer W1 is supplied to the expanding main body 200 in a posture suitable for expansion.

Then, after the expansion, etc., the wafer ring structure W in the second state is delivered from the clamp unit 214 to the cool air supplier 206. Then, the wafer ring structure W in the second state is delivered from the cool air supplier 206 to the suction hand unit 204. Then, during transportation from the suction hand unit 204 to the lift-up hand unit 203, the wafer ring structure W in the second state is inverted by the inversion mechanism 204d. Then, the wafer ring structure W in the first state, in which the sheet member W2 is arranged on the upper side and the wafer W1 is arranged on the lower side, is delivered from the suction hand unit 204 to the lift-up hand unit 203. Then, the wafer ring structure W in the first state is stored in the cassette unit 202 by the lift-up hand unit 203.

The semiconductor wafer processing apparatus 100 can also process the wafer ring structure W without inverting it. When the wafer ring structure W is not inverted, the wafer ring structure W is stored in the cassette unit 202 such that the sheet member W2 is arranged on the lower side, the wafer W1 is arranged on the upper side, and the circuit layer W11 is arranged on the upper side. In such a case, the wafer ring structure W is supplied to the dicing device 1 by the suction hand unit 204 without being inverted. The wafer ring structure W is also supplied to the expanding main body 200 by the suction hand unit 204 without being inverted.

### Advantageous Effects of First Embodiment

According to the first embodiment, the following advantageous effects are achieved.

According to the first embodiment, as described above, the suction hand unit 204 includes the inversion mechanism 204d configured to invert the posture of the wafer ring structure W. Accordingly, the inversion mechanism 204d is provided by effectively using the suction hand unit 204, and thus it is not necessary to provide the inversion mechanism 204d separately and independently. Consequently, the complexity of the structure can be reduced or prevented. Furthermore, the wafer ring structure W can be inverted by the inversion mechanism 204d. Consequently, the wafer ring structure W can be inverted by the inversion mechanism 204d while the complexity of the structure is reduced or prevented.

According to the first embodiment, as described above, the inversion mechanism 204d is configured to invert the posture of the wafer ring structure W by rotating the suction hand 204c of the suction hand unit 204 that is suctioning the wafer ring structure W about the rotation axis Ax extending in the horizontal direction. Accordingly, the wafer W1 can be reliably held by suction, and thus the wafer W1 can be stably inverted and transported.

According to the first embodiment, as described above, the semiconductor wafer processing apparatus 100 further includes the expanding main body 200 configured to expand the sheet member W2 to which the wafer W1 diced by the dicing device 1 has been attached, the lift-up hand unit 203 and the suction hand unit 204 are configured to transport the wafer ring structure W between the dicing device 1 and the expanding main body 200, the cassette unit 202 is configured to store the wafer ring structure W including the ring-shaped member W3 surrounding the wafer W1, and the suction hand unit 204 is configured to supply the wafer ring structure W to the dicing device 1 without inverting the wafer ring structure W using the inversion mechanism 204d, and to invert the wafer ring structure W using the inversion mechanism 204d and supply the wafer ring structure W to the expanding main body 200. In the case of the wafer ring structure W including the ring-shaped member W3, the wafer W1 is supplied in a posture suitable for dicing. However, when the posture of the wafer W1 suitable for dicing is opposite to the posture of the wafer W1 suitable for expansion, the posture of the wafer W1 suitable for dicing does not match the posture of the wafer W1 suitable for expansion. Therefore, with the configuration described above, even in the case of the wafer ring structure W including the ring-shaped member W3, in which the posture of the wafer W1 suitable for dicing does not match the posture of the wafer W1 suitable for expansion, the wafer ring structure W is inverted by the inversion mechanism 204d such that dicing and expansion can be appropriately performed.

According to the first embodiment, as described above, the expanding main body 200 includes the cool air supplier 206 configured to cool the sheet member W2 when expanding the sheet member W2, and the suction hand unit 204 is configured to invert the wafer ring structure W using the inversion mechanism 204d and deliver the wafer ring structure W to the cool air supplier 206. Accordingly, the wafer W1 is delivered by effectively using the cool air supplier 206, and thus it is not necessary to provide a receiving portion for the wafer W1 independent of the cool air supplier 206. Consequently, the complexity of the structure can be reduced or prevented as compared with a case in which a receiving portion for the wafer W1 is provided independent of the cool air supplier 206.

According to the first embodiment, as described above, the wafer transporter includes the lift-up hand unit 203 configured to take out the wafer ring structure W from the cassette unit 202, and the suction hand unit 204 configured to transport the taken-out wafer ring structure W, and the inversion mechanism 204d is provided in the suction hand unit 204. Accordingly, the lift-up hand unit 203 and the suction hand unit 204 are provided separately from each other, and thus the wafer ring structure W can be easily taken out from the cassette unit 202, and the taken-out wafer ring structure W can be easily transported. Furthermore, the inversion mechanism 204d is provided in the suction hand unit 204 such that the wafer ring structure W can be easily inverted by the inversion mechanism 204d.

### Second Embodiment

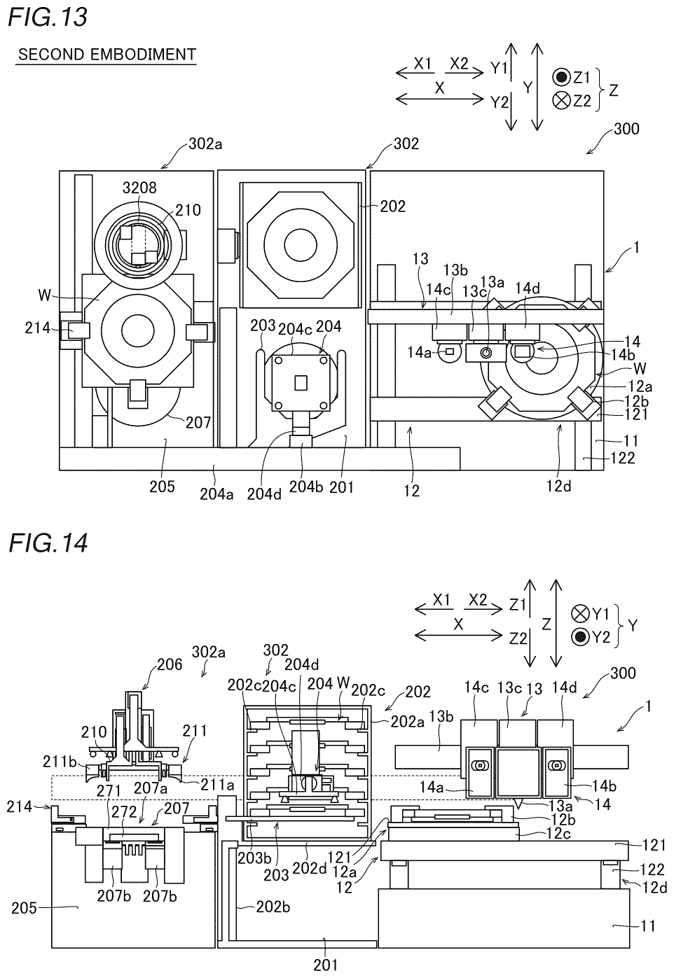

The configuration of a semiconductor wafer processing apparatus 300 according to a second embodiment is now described with reference to FIGS. 13 to 18. In the second embodiment, a squeegee unit 3213 is arranged outside an expanding ring 3281, unlike the first embodiment. In the second embodiment, detailed description of the same or similar configurations as those of the first embodiment is omitted. The semiconductor wafer processing apparatus 300 is an example of a “wafer processing apparatus” in the claims.

### Semiconductor Wafer Processing Apparatus

As shown in FIGS. 13 and 14, the semiconductor wafer processing apparatus 300 is an apparatus that processes a wafer W1 provided on a wafer ring structure W.

The semiconductor wafer processing apparatus 300 includes a dicing device 1 and an expanding device 302. An upward-downward direction is defined as a Z direction, an upward direction is defined as a Z1 direction, and a downward direction is defined as a Z2 direction. In a horizontal direction perpendicular to the Z direction, a direction in which the dicing device 1 and the expanding device 302 are aligned is defined as an X direction, a direction from the dicing device 1 toward the expanding device 302 in the X direction is defined as an X1 direction, and a direction from the expanding device 302 toward the dicing device 1 in the X direction is defined as an X2 direction. A direction perpendicular to the X direction in the horizontal direction is defined as a Y direction, one direction in the Y direction is defined as a Y1 direction, and the other direction in the Y direction is defined as a Y2 direction.

### Dicing Device

The dicing device 1 emits a laser having a wavelength transmissive to the wafer W1 along a dividing line (street) to form a modified layer.

Specifically, the dicing device 1 includes a base 11, a chuck table unit 12, a laser 13, and an imager 14.

### Expanding Device

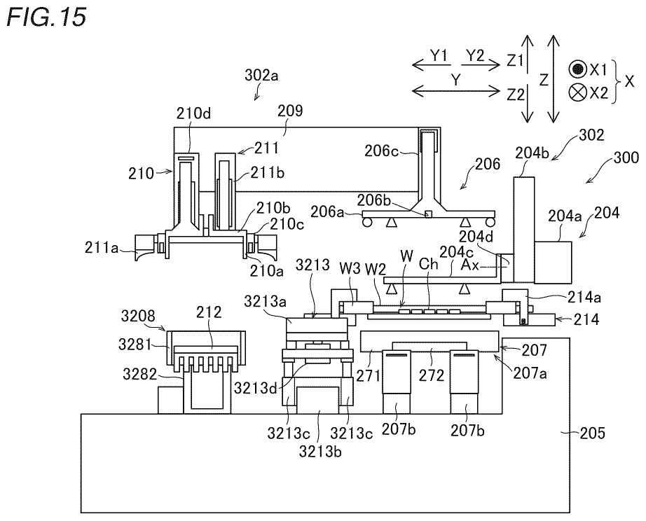

As shown in FIGS. 14 and 15, the expanding device 302 divides the wafer W1 to form a plurality of semiconductor chips Ch.

The expanding device 302 includes an expanding main body 302a, a base 201, a cassette unit 202, a lift-up hand unit 203, and a suction hand unit 204. The expanding main body 302a expands a sheet member W2 to which the wafer W1 (having the modified layer formed thereon) that has been diced by the dicing device 1 has been attached. The expanding main body 302a includes a base 205, a cool air supplier 206, a cooling unit 207, an expander 3208, a base 209, an expansion maintaining member 210, a heat shrinker 211, an ultraviolet irradiator 212, a squeegee unit 3213, and a clamp unit 214. The expanding main body 302a is an example of an “expander” in the claims.

### Expander

The expander 3208 expands a sheet member W2 of the wafer ring structure W to divide the wafer W1 along the dividing line.

Specifically, the expander 3208 includes the expanding ring 3281 and a Z-direction movement mechanism 3282.

The expanding ring 3281 expands the sheet member W2 by supporting the sheet member W2 from the Z2 direction side. The expanding ring 3281 has a ring shape in a plan view. The Z-direction movement mechanism 3282 moves the expanding ring 3281 in the Z1 direction or the Z2 direction. The Z-direction movement mechanism 3282 includes a linear conveyor module, or a ball screw and a drive including a motor with an encoder, for example. The Z-direction movement mechanism 3282 is attached to the base 205.

### Squeegee Unit

The squeegee unit 3213 further divides the wafer W1 along the modified layer by pressing the wafer W1 from the Z2 direction side after the sheet member W2 is expanded. Specifically, the squeegee unit 3213 includes a press 3213a, an X-direction movement mechanism 3213b, a Z-direction movement mechanism 3213c, and a rotation mechanism 3213d.

The press 3213a generates a bending stress in the wafer W1 to divide the wafer W1 along the modified layer by being moved by the rotation mechanism 3213d and the X-direction movement mechanism 3213b while pressing the wafer W1 from the Z2 direction side via the sheet member W2 after being moved in the Z1 direction by the Z-direction movement mechanism 3213c. The press 3213a is a squeegee. The press 3213a is attached to an end of the rotation mechanism 3213d on the Z1 direction side. The Z-direction movement mechanism 3213c moves the rotation mechanism 3213d in the Z1 direction or the Z2 direction. The Z-direction movement mechanism 3213c includes a cylinder, for example. The Z-direction movement mechanism 3213c is attached to an end of the X-direction movement mechanism 3213b on the Z1 direction side. The X-direction movement mechanism 3213b includes a linear conveyor module, or a ball screw and a drive including a motor with an encoder, for example. The X-direction movement mechanism 3213b is attached to an end of the base 205 on the Z1 direction side.

In the squeegee unit 3213, the press 3213a divides the wafer W1 by being moved in the Y direction by the X-direction movement mechanism 3213b while pressing the wafer W1 from the Z2 direction side via the sheet member W2 after being moved in the Z1 direction by the Z-direction movement mechanism 3213c. Furthermore, in the squeegee unit 3213, after the press 3213a finishes moving in the Y direction, the press 3213a is rotated 90 degrees by the rotation mechanism 3213d. Moreover, in the squeegee unit 3213, the press 3213a divides the wafer W1 by being moved in the X direction by the X-direction movement mechanism 3213b while pressing the wafer W1 from the Z2 direction side via the sheet member W2 after being rotated 90 degrees.

Although detailed description is omitted, the suction hand unit 204 includes an inversion mechanism 204d to invert the posture of the wafer ring structure W, and inversion of the wafer ring structure W by the inversion mechanism 204d is similar to that in the first embodiment described above.

### Control Configuration of Semiconductor Wafer Processing Apparatus

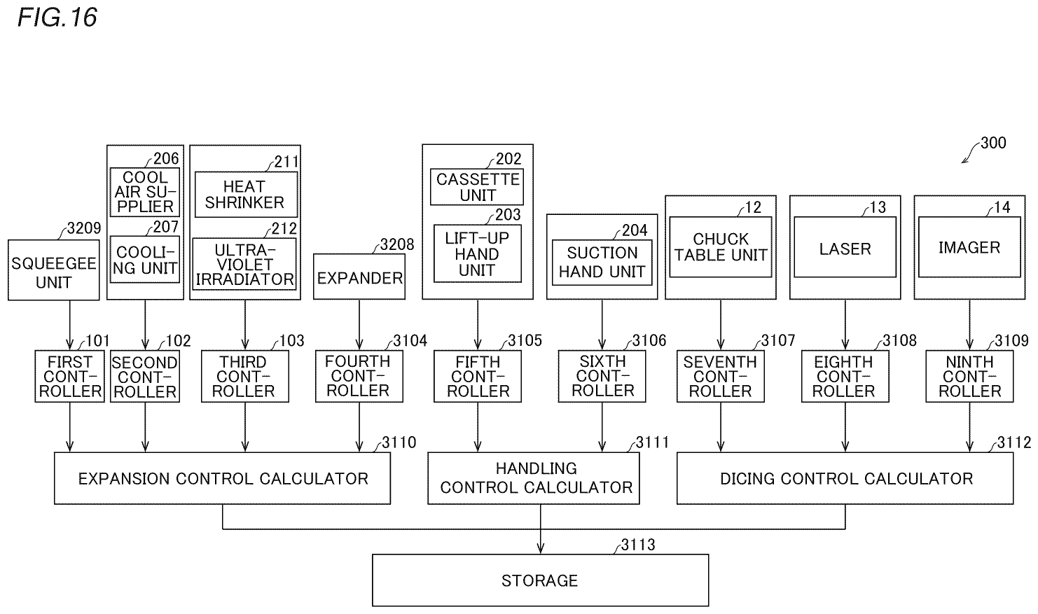

As shown in FIG. 16, the semiconductor wafer processing apparatus 300 includes a first controller 101, a second controller 102, a third controller 103, a fourth controller 3104, a fifth controller 3105, a sixth controller 3106, a seventh controller 3107, an eighth controller 3108, a ninth controller 3109, an expansion control calculator 3110, a handling control calculator 3111, a dicing control calculator 3112, and a storage 3113. The first controller 101, the second controller 102, the third controller 103, the fifth controller 3105, the sixth controller 3106, the seventh controller 3107, the eighth controller 3108, the ninth controller 3109, the expansion control calculator 3110, the handling control calculator 3111, the dicing control calculator 3112, and the storage 3113 have the same configurations as the first controller 101, the second controller 102, the third controller 103, the fourth controller 104, the fifth controller 105, the sixth controller 106, the seventh controller 107, the eighth controller 108, the expansion control calculator 109, the handling control calculator 110, the dicing control calculator 111, and the storage 112 according to the first embodiment, respectively, and thus description thereof is omitted.

The fourth controller 3104 controls the expander 3208. The fourth controller 3104 includes a CPU and a storage including a ROM and a RAM, for example. The fourth controller 3104 may include, as a storage, an HDD that retains stored information even after the voltage is cut off, for example.

### Semiconductor Chip Manufacturing Process

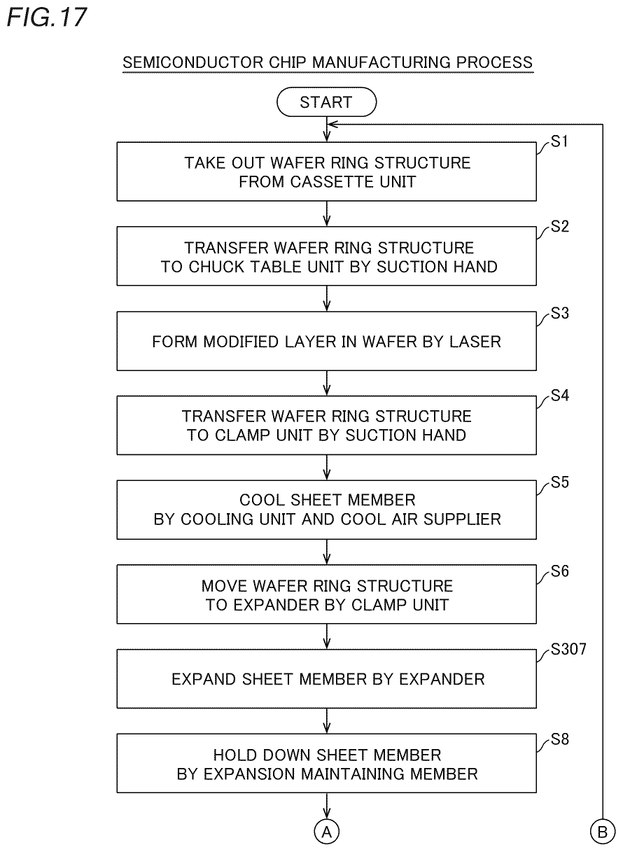

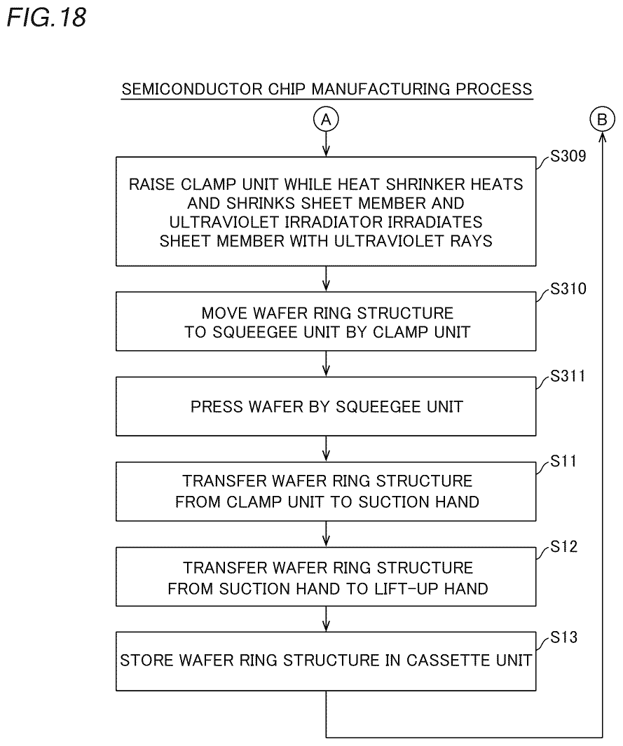

The overall operation of the semiconductor wafer processing apparatus 300 is described below with reference to FIGS. 17 and 18.

Process operations in step S1 to step S6, step S8, and step S11 are the same as the process operations in step S1 to step S6, step S8, and step S11 in the semiconductor chip manufacturing process according to the first embodiment, respectively, and thus description thereof is omitted.

In step S307, the sheet member W2 is expanded by the expander 3208. That is, the expanding ring 3281 is moved in the Z1 direction by the Z-direction movement mechanism 3282. The wafer ring structure W is moved in the Z2 direction by a Z-direction movement mechanism 214b while being held by the clamp unit 214. Then, the sheet member W2 is expanded by contacting the expanding ring 3281 and being pulled by the expanding ring 3281. Thus, the wafer W1 is divided along the dividing line (modified layer).

As shown in FIG. 18, in step S309, while the heat shrinker 211 heats and shrinks the sheet member W2 and the ultraviolet irradiator 212 irradiates the sheet member W2 with ultraviolet rays, the clamp unit 214 is raised. At this time, an intake 210c takes in air in the vicinity of the heated sheet member W2. In step S310, the wafer ring structure W is moved to the squeegee unit 3213 by the clamp unit 214. That is, the wafer ring structure W is moved in the Y2 direction by a Y-direction movement mechanism 214c while being held by the clamp unit 214.

In step S311, after the wafer ring structure W is moved to the squeegee unit 3213, the wafer W1 is pressed by the squeegee unit 3213. Thus, the wafer W1 is further divided by the squeegee unit 3213. The remaining configurations of the second embodiment are similar to those of the first embodiment.

### Advantageous Effects of Second Embodiment

According to the second embodiment, the following advantageous effects are achieved.

According to the second embodiment, as described above, the suction hand unit 204 includes the inversion mechanism 204d to invert the posture of the wafer ring structure W. Accordingly, similarly to the first embodiment, the wafer ring structure W can be inverted by the inversion mechanism 204d while the complexity of the structure is reduced or prevented. The remaining advantageous effects of the second embodiment are similar to those of the first embodiment.

### Third Embodiment

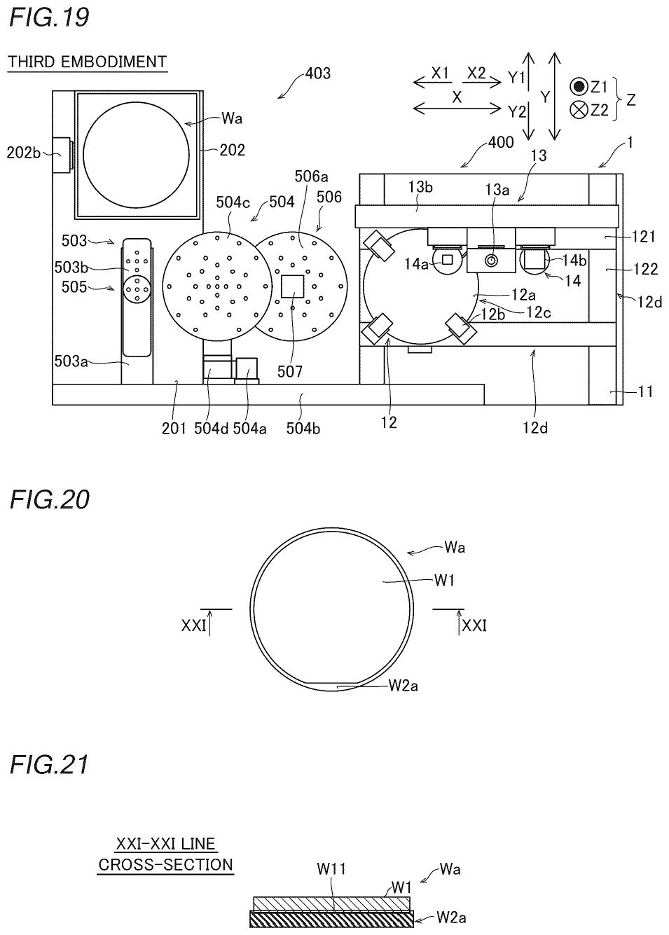

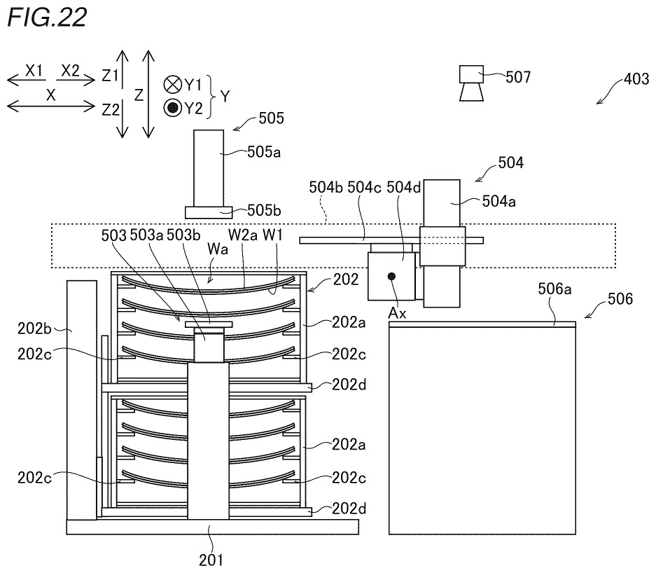

The configuration of a semiconductor wafer processing apparatus 400 according to a third embodiment is now described with reference to FIGS. 19 to 25. In the third embodiment, a wafer structure Wa including no ring-shaped member is diced, unlike the first embodiment and the second embodiment. In the third embodiment, detailed description of the same or similar configurations as those of the first or second embodiment is omitted. The semiconductor wafer processing apparatus 400 is an example of a “wafer processing apparatus” in the claims.

### Semiconductor Wafer Processing Apparatus

As shown in FIG. 19, the semiconductor wafer processing apparatus 400 is an apparatus that processes a wafer W1 provided on the wafer structure Wa.

The wafer structure Wa is described with reference to FIGS. 20 and 21. The wafer structure Wa includes the wafer W1 and a sheet member W2a, and does not include a ring-shaped member. The sheet member W2a is an adhesive tape for back grinding made of a harder material, which is not elastic, as compared with the sheet member W2 for expansion in the first and second embodiments. An adhesive layer is provided on the upper surface of the sheet member W2a. The wafer W1 is attached to the adhesive layer of the sheet member W2a. In the third embodiment, the wafer W1 is arranged on the sheet member W2a such that a circuit layer W11 is arranged on the sheet member W2a side.

As shown in FIG. 19, the semiconductor wafer processing apparatus 400 includes a dicing device 1 and a wafer supply device 403. An upward-downward direction is defined as a Z direction, an upward direction is defined as a Z1 direction, and a downward direction is defined as a Z2 direction. In a horizontal direction perpendicular to the Z direction, a direction in which the dicing device 1 and the wafer supply device 403 are aligned is defined as an X direction, a direction from the dicing device 1 toward the wafer supply device 403 in the X direction is defined as an X1 direction, and a direction from the wafer supply device 403 toward the dicing device 1 in the X direction is defined as an X2 direction. A direction perpendicular to the X direction in the horizontal direction is defined as a Y direction, one direction in the Y direction is defined as a Y1 direction, and the other direction in the Y direction is defined as a Y2 direction.

### Dicing Device

The dicing device 1 emits a laser having a wavelength transmissive to the wafer W1 along a dividing line (street) to form a modified layer.

Specifically, the dicing device 1 includes a base 11, a chuck table unit 12, a laser 13, and an imager 14.

### Wafer Supply Device

As shown in FIGS. 19 and 21, the wafer supply device 403 supplies the wafer W1 (wafer structure Wa).

The wafer supply device 403 includes a base 201, a cassette unit 202, a lift-up hand unit 503, suction hand units 504 and 505, a temporary placement unit 506, and an imager 507. The lift-up hand unit 503 and the suction hand units 504 and 505 are examples of a “wafer transporter” in the claims. The lift-up hand unit 503 is an example of an “taking-out unit” in the claims. The suction hand unit 504 is an example of a “suction unit” or “transport mechanism” in the claims.

### Base

The base 201 is a base on which the cassette unit 202 and the lift-up hand unit 503 are installed.

### Cassette Unit

The cassette unit 202 can accommodate a plurality of wafer structures Wa. In the third embodiment, the wafer structure Wa is stored in the cassette unit 202 such that the sheet member W2 is arranged on the upper side, the wafer W1 is arranged on the lower side, and the circuit layer W11 is arranged on the upper side. Moreover, the wafer structure Wa is stored in the cassette unit 202 so as to bend downward. The cassette unit 202 includes wafer cassettes 202a, a Z-direction movement mechanism 202b, and pairs of placement portions 202c.

### Lift-Up Hand Unit

The lift-up hand unit 503 can take out the wafer structure Wa from the cassette unit 202. Furthermore, the lift-up hand unit 503 can take the wafer structure Wa into the cassette unit 202.

Specifically, the lift-up hand unit 503 includes a Y-direction movement mechanism 503a and a lift-up hand 503b. The Y-direction movement mechanism 503a includes a linear conveyor module, or a ball screw and a drive including a motor with an encoder, for example. The lift-up hand 503b generates a negative pressure to suction and support the wafer W1 of the wafer structure Wa from the Z2 direction side. The lift-up hand 503b includes a suction hole or the like to suction the wafer structure Wa by the negative pressure. The lift-up hand 503b is I-shaped, extending in the Y direction in a plan view.

### Suction Hand Unit

The suction hand unit 505 suctions the sheet member W2a of the wafer structure Wa from the Z1 direction side.

Specifically, the suction hand unit 505 includes a Z-direction movement mechanism 505a and a suction hand 505b. The Z-direction movement mechanism 505a moves the suction hand 505b in the Z direction. The Z-direction movement mechanism 505a includes a linear conveyor module, or a ball screw and a drive including a motor with an encoder, for example. The suction hand 505b generates a negative pressure to suction and support the sheet member W2a of the wafer structure Wa from the Z1 direction side. The suction hand 505b includes a suction hole or the like to suction the wafer structure Wa by the negative pressure.

The suction hand 505b has a circular shape in the plan view.

The suction hand unit 504 suctions the wafer structure Wa.

Specifically, the suction hand unit 504 includes an X-direction movement mechanism 504a, a Z-direction movement mechanism 504b, a suction hand 504c, and an inversion mechanism 504d. The X-direction movement mechanism 504a moves the suction hand 504c in the X direction. The Z-direction movement mechanism 504b moves the suction hand 504c in the Z direction. Each of the X-direction movement mechanism 504a and the Z-direction movement mechanism 504b includes a linear conveyor module, or a ball screw and a drive including a motor with an encoder, for example. The suction hand 504c generates a negative pressure to suction and support the wafer structure Wa. The suction hand 504c includes a suction hole or the like to suction the wafer structure Wa by the negative pressure. The suction hand 504c has a circular shape with a diameter equal to or larger than the diameter of the wafer structure Wa in the plan view, and can suction substantially the entire wafer structure Wa.

The wafer transporter includes the lift-up hand unit 503 and the suction hand units 504 and 505, and transports the wafer structure Wa between the cassette unit 202 and the dicing device 1. In the third embodiment, the wafer transporter includes the lift-up hand unit 503 to take out the wafer structure Wa from the cassette unit 202, and the suction hand units 504 and 505 to transport the taken-out wafer structure Wa.

In the third embodiment, the suction hand unit 504 includes the inversion mechanism 504d to invert the posture of the wafer structure Wa. In the third embodiment, the inversion mechanism 504d is provided in the suction hand unit 504. In the third embodiment, the inversion mechanism 504d inverts the posture of the wafer structure Wa by rotating the suction hand 504c of the suction hand unit 504 that is suctioning the wafer structure Wa about a rotation axis Ax extending in the horizontal direction (Y direction). The inversion mechanism 504d includes a motor and a rotation shaft rotated by the motor. The rotation shaft of the inversion mechanism 504d is connected to the suction hand 504c so as to be able to rotate the suction hand 504c about the rotation axis Ax.

In the third embodiment, the suction hand unit 504 inverts the wafer structure Wa using the inversion mechanism 504d and supplies it to the dicing device 1. Specifically, the suction hand unit 504 supplies the wafer structure Wa, in which the sheet member W2 is arranged on the lower side and the wafer W1 is arranged on the upper side, to the dicing device 1, by inverting the wafer structure Wa, in which the sheet member W2 is arranged on the upper side and the wafer W1 is arranged on the lower side, using the inversion mechanism 504d. In the third embodiment, the suction hand unit 504 inverts the wafer structure Wa using the inversion mechanism 504d and places the wafer structure Wa on the temporary placement unit 506 before supplying the wafer structure Wa to the dicing device 1.

### Temporary Placement Unit

The temporary placement unit 506 is a table on which the wafer structure Wa is temporarily placed before the wafer structure Wa is supplied to the dicing device 1. The temporary placement unit 506 is provided between the cassette unit 202 and the dicing device 1. The wafer structure Wa to be diced next (in which a modified layer is to be formed) is placed on the temporary placement unit 506. The temporary placement unit 506 includes a suction surface 506a on its upper surface. The suction surface 506a generates a negative pressure to suction and support the wafer structure Wa. The suction surface 506a includes a suction hole or the like to suction the wafer structure Wa by the negative pressure. The suction surface 506a has a circular shape with a diameter equal to or larger than the diameter of the wafer structure Wa in the plan view, and can suction substantially the entire wafer structure Wa.

### Imager

The imager 507 is a camera that images the wafer W1 of the wafer structure Wa placed on the temporary placement unit 506. Based on the imaging result of the wafer W1 of the wafer structure Wa by the imager 507, deviations of the wafer W1 in the X and Y directions and a rotational deviation of the wafer W1 within an X-Y plane can be acquired. Furthermore, after the wafer structure Wa is transferred to the chuck table unit 12, the position of the wafer W1 of the wafer structure Wa on the chuck table unit 12 can be corrected based on the deviations of the wafer W1 in the X and Y directions and the rotational deviation of the wafer W1 within the X-Y plane.

### Inversion of Wafer Structure

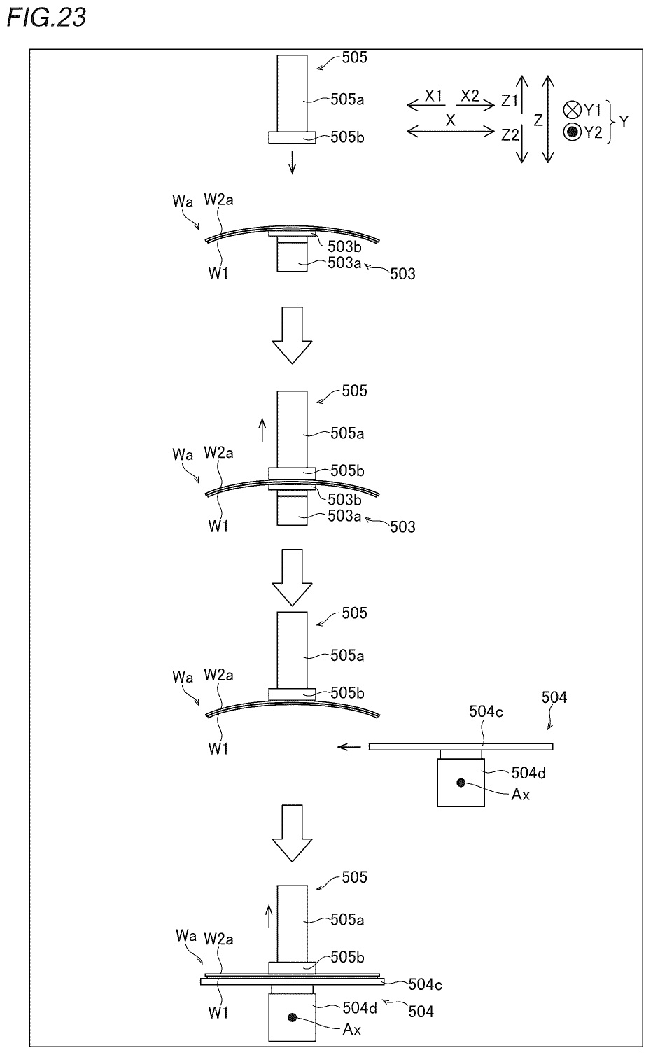

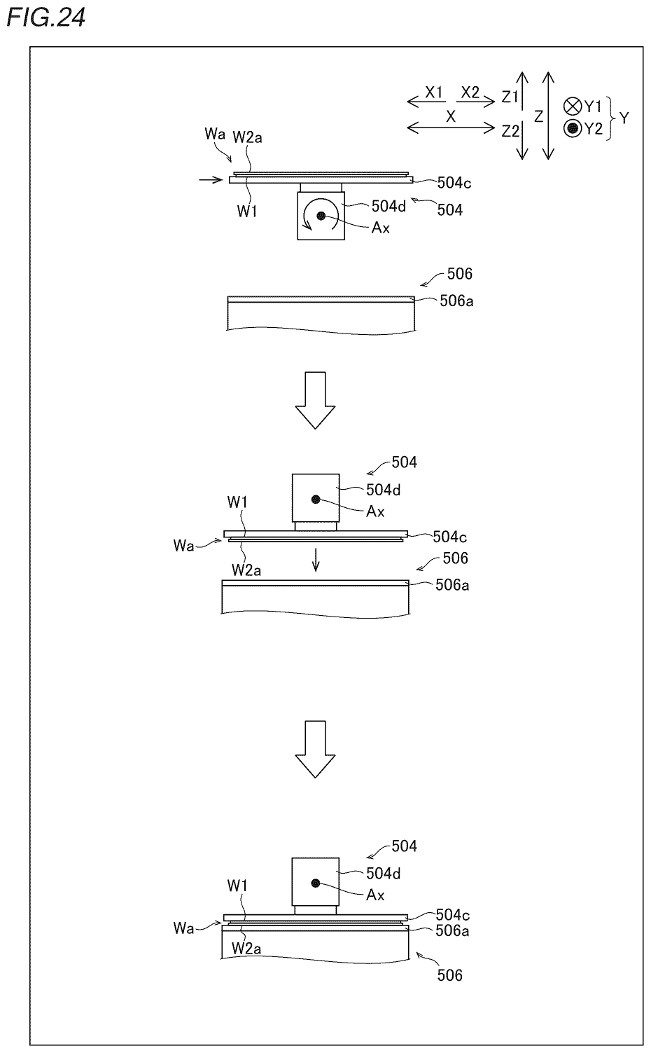

The inversion of the wafer structure Wa is described with reference to FIGS. 23 and 24.

First, the lift-up hand 503b of the lift-up hand unit 503 is moved in the Y1 direction by the Y-direction movement mechanism 503a and is moved into the cassette unit 202. Then, the lift-up hand 503b suctions and supports the wafer structure Wa from the Z2 direction side in the cassette unit 202. Then, while the lift-up hand 503b suctions and supports the wafer structure Wa from the Z2 direction side, the lift-up hand 503b is moved in the Y2 direction by the Y-direction movement mechanism 503a and is moved to the outside of the cassette unit 202. Then, the wafer structure Wa in which the sheet member W2a is arranged on the upper side and the wafer W1 is arranged on the lower side (hereinafter referred to as the wafer structure Wa in the first state) is taken out from the cassette unit 202 by the lift-up hand unit 503. Then, as shown in FIG. 23, the suction hand 505b of the suction hand unit 505 is moved in the Z2 direction by the Z-direction movement mechanism 505a. Then, the wafer structure Wa in the first state is suctioned and supported by the suction hand unit 505, and the suction by the lift-up hand unit 503 is released such that the wafer structure Wa in the first state is delivered from the lift-up hand unit 503 to the suction hand unit 505. Then, the suction hand 505b of the suction hand unit 505 is moved in the Z1 direction by the Z-direction movement mechanism 505a.

Then, the suction hand 504c of the suction hand unit 504 is moved in the X1 direction by the X-direction movement mechanism 504a and is moved to a position below the suction hand 505b of the suction hand unit 505. At this time, the suction surface of the suction hand 504c of the suction hand unit 504 faces the Z1 direction side (suction hand 505b side). Then, the suction hand 505b of the suction hand unit 505 is moved in the Z2 direction by the Z-direction movement mechanism 505a. Then, the wafer structure Wa in the first state is suctioned and supported by the suction hand unit 504, and the suction by the suction hand unit 505 is released such that the wafer structure Wa in the first state is delivered from the suction hand unit 505 to the suction hand unit 504.

As shown in FIG. 24, the wafer structure Wa in the first state is inverted by the inversion mechanism 504d during transportation to the dicing device 1. The wafer structure Wa in which the sheet member W2a is arranged on the lower side and the wafer W1 is arranged on the upper side (hereinafter referred to as the wafer structure Wa in the second state) is supplied to the dicing device 1 by the suction hand unit 504. Specifically, before being supplied to the dicing device 1, the wafer structure Wa in the second state is placed on the suction surface 506a of the temporary placement unit 506 by the suction hand unit 504.

At this time, the suction hand 504c of the suction hand unit 504 is moved in the X2 direction by the X-direction movement mechanism 504a and is moved to a position above the suction surface 506a of the temporary placement unit 506. Then, the suction hand 504c of the suction hand unit 504 is moved in the Z2 direction by the Z-direction movement mechanism 504b. Then, the wafer structure Wa in the second state is suctioned and supported by the temporary placement unit 506, and the suction by the suction hand unit 504 is released such that the wafer structure Wa in the second state is delivered from the suction hand unit 504 to the temporary placement unit 506. In the dicing device 1, dicing (formation of a modified layer) is performed on the wafer structure Wa supplied to the dicing device 1 before the wafer structure Wa placed on the temporary placement unit 506.

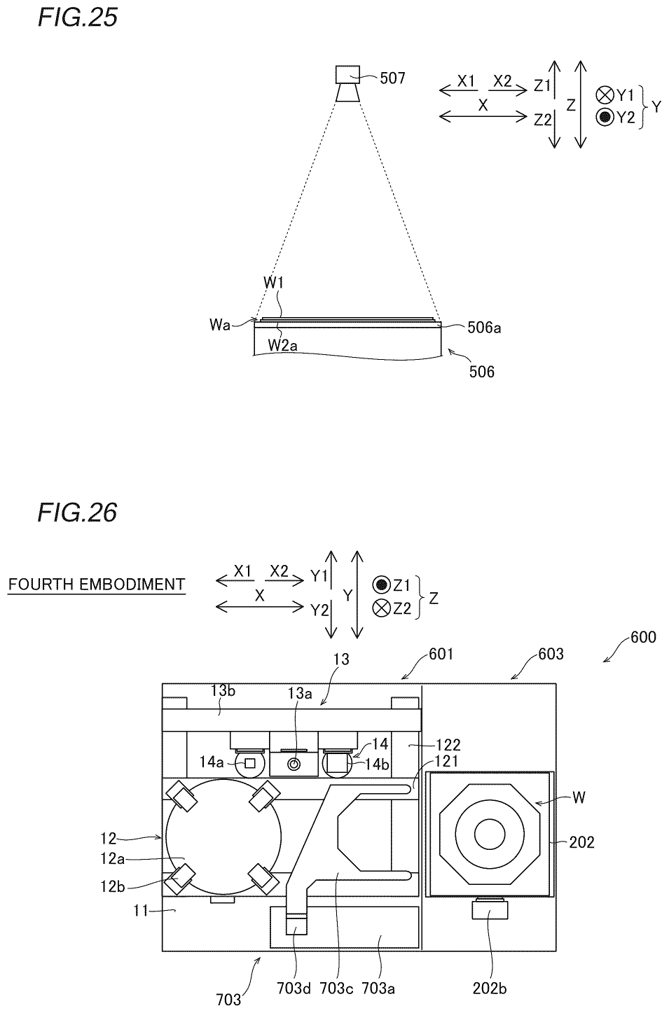

As shown in FIG. 25, the wafer W1 of the wafer structure Wa in the second state is imaged by the imager 507 while the wafer W1 is placed on the temporary placement unit 506. Based on the imaging result of the wafer W1 by the imager 507, the deviations of the wafer W1 in the X and Y directions and the rotational deviation of the wafer W1 within the X-Y plane are acquired.

Then, when dicing (formation of a modified layer) for the previous wafer structure Wa is completed, the wafer structure Wa for which dicing has been completed is transported from the dicing device 1 to the cassette unit 202. The procedure for transporting the wafer structure Wa from the dicing device 1 to the cassette unit 202 is generally opposite to the procedure for transporting the wafer structure Wa from the cassette unit 202 to the dicing device 1.

That is, the wafer structure Wa in the second state is delivered from the chuck table unit 12 of the dicing device 1 to the suction hand unit 504. At this time, the suction surface of the suction hand 504c of the suction hand unit 504 faces the Z2 direction side (chuck table unit 12 side). Then, the suction hand unit 504 is moved in the X1 direction by the X-direction movement mechanism 504a and is moved to a position below the suction hand unit 505. During this movement, the wafer structure Wa in the second state is inverted by the inversion mechanism 504d. Then, the wafer structure Wa in the first state, in which the sheet member W2a is arranged on the upper side and the wafer W1 is arranged on the lower side, is delivered from the suction hand unit 504 to the lift-up hand unit 503 via the suction hand unit 505. Then, the lift-up hand 503b of the lift-up hand unit 503 is moved in the Y1 direction by the Y-direction movement mechanism 503a and is moved into the cassette unit 202. Then, the wafer structure Wa in the first state is delivered from the lift-up hand unit 503 to the cassette unit 202 and is stored in the cassette unit 202.

After the wafer structure Wa in the first state is delivered from the suction hand unit 504 to the suction hand unit 505, the suction hand 504c of the suction hand unit 504 that is in an empty state in which the suction hand 504c does not suction the wafer structure Wa is moved in the X2 direction by the X-direction movement mechanism 504a and is moved to a position above the wafer structure Wa placed on the temporary placement unit 506. At this time, the suction surface of the suction hand 504c of the suction hand unit 504 faces the Z2 direction side (temporary placement unit 506 side). Then, the suction hand 504c of the suction hand unit 504 is moved in the Z2 direction by the Z-direction movement mechanism 504b. Then, the wafer structure Wa in the second state is suctioned and supported by the suction hand unit 504, and the suction by the temporary placement unit 506 is released such that the wafer structure Wa in the second state is delivered from the temporary placement unit 506 to the suction hand unit 504.

Then, the suction hand 504c of the suction hand unit 504 is moved in the Z1 direction by the Z-direction movement mechanism 504b and in the X2 direction by the X-direction movement mechanism 504a to a position above the chuck table unit 12. Then, the suction hand 504c of the suction hand unit 504 is moved in the Z2 direction by the Z-direction movement mechanism 504b. Then, the wafer structure Wa in the second state is supported by the chuck table unit 12, and the suction by the suction hand unit 504 is released such that the wafer structure Wa in the second state is delivered from the suction hand unit 504 to the chuck table unit 12.

Then, the modified layer is formed by emitting a laser beam to the wafer structure Wa in the second state by the laser 13. At this time, the laser beam is emitted to the wafer W1 from the side opposite to the circuit layer W11 by the laser 13. Therefore, similarly to the first embodiment, it is possible to prevent the width of the laser beam from not fitting within the width of the street. Thus, the wafer W1 is supplied to the dicing device 1 in a posture suitable for dicing. The remaining configurations of the third embodiment are similar to those of the first embodiment.

### Advantageous Effects of Third Embodiment

According to the third embodiment, the following advantageous effects are achieved.

According to the third embodiment, as described above, the suction hand unit 504 includes the inversion mechanism 504d configured to invert the position of the wafer structure Wa. Accordingly, similarly to the first embodiment, the wafer structure Wa can be inverted by the inversion mechanism 504d while the complexity of the structure is reduced or prevented.

According to the third embodiment, as described above, the cassette unit 202 is configured to store the wafer structure Wa that does not include a ring-shaped member surrounding the wafer W1, and the wafer W1 transporter is configured to invert the wafer structure Wa using the inversion mechanism 504d and supply the wafer structure Wa to the dicing device 1. In the case of the wafer structure Wa that does not include a ring-shaped member, the wafer W1 may not be supplied in a posture suitable for dicing. Therefore, with the configuration described above, even in the case of the wafer structure Wa that does not include a ring-shaped member, in which the wafer W1 is not supplied in a posture suitable for dicing, the wafer W1 can be placed in a posture suitable for dicing by inverting the wafer structure Wa using the inversion mechanism 504d, and thus dicing can be performed appropriately.

According to the third embodiment, as described above, the semiconductor wafer processing apparatus 400 includes the temporary placement unit 506 provided between the cassette unit 202 and the dicing device 1 and configured to allow the wafer structure Wa to be placed thereon, and the suction hand unit 504 is configured to invert the wafer structure Wa using the inversion mechanism 504d and place the wafer structure Wa on the temporary placement unit 506 before supplying the wafer structure Wa to the dicing device 1. Accordingly, the next wafer W1 can be prepared in an inverted state on the temporary placement unit 506, and thus the next wafer W1 can be quickly supplied to the dicing device 1. The remaining advantageous effects of the third embodiment are similar to those of the first embodiment.

### Fourth Embodiment

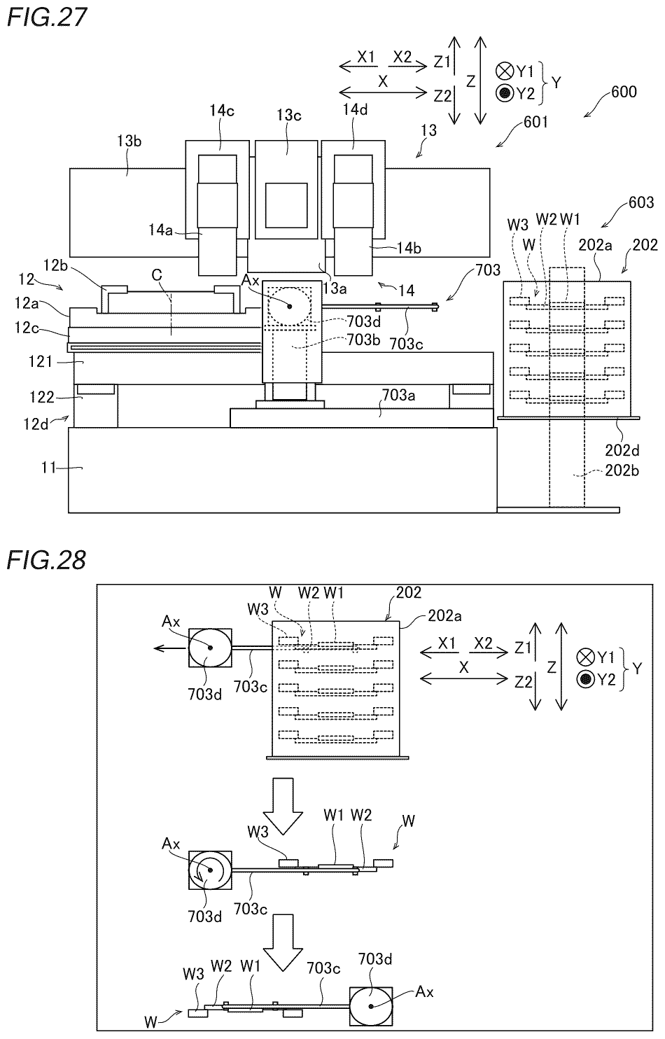

The configuration of a semiconductor wafer processing apparatus 600 according to a fourth embodiment is now described with reference to FIGS. 26 and 27. In the fourth embodiment, a lift-up hand unit 703 includes an inversion mechanism 703d, unlike the first to third embodiments. In the fourth embodiment, detailed description of the same or similar configurations as those of the first, second, or third embodiment is omitted. The semiconductor wafer processing apparatus 600 is an example of a “wafer processing apparatus” in the claims. The lift-up hand unit 703 is an example of a “wafer transporter” or a “take-out transporter” in the claims.

### Semiconductor Wafer Processing Apparatus

As shown in FIGS. 26 and 27, the semiconductor wafer processing apparatus 600 is an apparatus that processes a wafer W1 provided on a wafer ring structure W.

The semiconductor wafer processing apparatus 600 includes a dicing device 601 and a wafer supply device 603. An upward-downward direction is defined as a Z direction, an upward direction is defined as a Z1 direction, and a downward direction is defined as a Z2 direction. In a horizontal direction perpendicular to the Z direction, a direction in which the dicing device 601 and the wafer supply device 603 are aligned is defined as an X direction, a direction from the dicing device 601 toward the wafer supply device 603 in the X direction is defined as an X2 direction, and a direction from the wafer supply device 603 toward the dicing device 601 in the X direction is defined as an X1 direction. A direction perpendicular to the X direction in the horizontal direction is defined as a Y direction, one direction in the Y direction is defined as a Y1 direction, and the other direction in the Y direction is defined as a Y2 direction. The dicing device 601 is an example of a “dicer” in the claims.

### Dicing Device

The dicing device 601 emits a laser having a wavelength transmissive to the wafer W1 along a dividing line (street) to form a modified layer.

Specifically, the dicing device 601 includes a base 11, a chuck table unit 12, a laser 13, an imager 14, and the lift-up hand unit 703.

### Wafer Supply Device

The wafer supply device 603 supplies the wafer W1 (wafer ring structure W).

The wafer supply device 603 includes a cassette unit 202. The cassette unit 202 can accommodate a plurality of wafer ring structures W. In the fourth embodiment, the wafer ring structure W is stored in the cassette unit 202 such that a sheet member W2 is arranged on the lower side, the wafer W1 is arranged on the upper side, and a circuit layer W11 is arranged on the upper side.

### Lift-Up Hand Unit

The lift-up hand unit 703 can take out the wafer ring structure W from the cassette unit 202 and transport the taken-out wafer ring structure W. Furthermore, the lift-up hand unit 703 can take the wafer ring structure W into the cassette unit 202. The lift-up hand unit 703 transports the wafer ring structure W between the cassette unit 202 and the dicing device 601.

Specifically, the lift-up hand unit 703 includes an X-direction movement mechanism 703a, a Z-direction movement mechanism 703b, and a lift-up hand 703c. The X-direction movement mechanism 703a moves the lift-up hand 703c in the X direction. The Z-direction movement mechanism 703b moves the lift-up hand 703c in the Z direction. Each of the X-direction movement mechanism 703a and the Z-direction movement mechanism 703b includes a linear conveyor module, or a ball screw and a drive including a motor with an encoder, for example. The lift-up hand 703c generates a negative pressure to suction and support a ring-shaped member W3 of the wafer ring structure W from the Z2 direction side. The lift-up hand 703c includes a suction hole or the like to suction the wafer ring structure W by the negative pressure.

In the fourth embodiment, the lift-up hand unit 703 includes the inversion mechanism 703d to invert the posture of the wafer ring structure W. In the fourth embodiment, the inversion mechanism 703d is provided in the lift-up hand unit 703. In the fourth embodiment, the inversion mechanism 703d inverts the posture of the wafer ring structure W by rotating the lift-up hand 703c of the lift-up hand unit 703 that is suctioning the wafer ring structure W about a rotation axis Ax extending in the horizontal direction (Y direction). The inversion mechanism 703d includes a motor and a rotation shaft rotated by the motor. The rotation shaft of the inversion mechanism 703d is connected to the lift-up hand 703c so as to be able to rotate the lift-up hand 703c about the rotation axis Ax. The lift-up hand 703c is rotated about the rotation axis Ax by the inversion mechanism 703d so as to be moved from one side to the other side with respect to the rotation axis Ax.

In the fourth embodiment, the lift-up hand unit 703 inverts the wafer ring structure W using the inversion mechanism 703d and supplies it to the dicing device 601. Specifically, the lift-up hand unit 703 supplies the wafer ring structure W, in which the sheet member W2 is arranged on the upper side and the wafer W1 is arranged on the lower side, to the dicing device 601, by inverting the wafer ring structure W, in which the sheet member W2 is arranged on the lower side and the wafer W1 is arranged on the upper side, using the inversion mechanism 703d.

### Inversion of Wafer Structure

The inversion of the wafer ring structure W is described with reference to FIG. 28.

As shown in FIG. 28, first, the lift-up hand 703c of the lift-up hand unit 703 is moved in the X2 direction by the X-direction movement mechanism 703a and is moved into the cassette unit 202. Then, the lift-up hand 703c suctions and supports the wafer ring structure W from the Z2 direction side in the cassette unit 202. Then, while the lift-up hand 703c suctions and supports the wafer ring structure W from the Z2 direction side, the lift-up hand 703c is moved in the X1 direction by the X-direction movement mechanism 703a and is moved to the outside of the cassette unit 202. Then, the wafer ring structure W in which the sheet member W2 is arranged on the lower side and the wafer W1 is arranged on the upper side (hereinafter referred to as the wafer ring structure W in the first state) is taken out from the cassette unit 202 by the lift-up hand unit 703.

Then, the wafer ring structure W in the first state is inverted by the inversion mechanism 703d during transportation to the chuck table unit 12. Then, the wafer ring structure W in which the sheet member W2 is arranged on the upper side and the wafer W1 is arranged on the lower side (hereinafter referred to as the wafer ring structure W in the second state) is supplied to the chuck table unit 12 by the lift-up hand unit 703. Specifically, the lift-up hand 703c of the lift-up hand unit 703 and the chuck table unit 12 are moved in the X direction, and the lift-up hand 703c is moved to a position above the chuck table unit 12. Then, the lift-up hand 703c is moved in the Z2 direction by the Z-direction movement mechanism 703b. Then, the wafer ring structure W in the second state is delivered from the lift-up hand unit 703 to the chuck table unit 12.

Then, the modified layer is formed by emitting a laser beam to the wafer ring structure W in the second state by the laser 13. At this time, the laser beam is emitted to the wafer W1 through the sheet member W2 from the side opposite to the circuit layer W11 by the laser 13. Therefore, similarly to the first embodiment, it is possible to prevent the width of the laser beam from not fitting within the width of the street. Thus, the wafer W1 is supplied to the dicing device 601 in a posture suitable for dicing.

Then, when dicing (formation of the modified layer) for the wafer structure Wa is completed, the wafer ring structure W for which dicing has been completed is transported from the chuck table unit 12 to the cassette unit 202. The procedure for transporting the wafer ring structure W from the chuck table unit 12 to the cassette unit 202 is generally opposite to the procedure for transporting the wafer ring structure W from the cassette unit 202 to the chuck table unit 12.

That is, the wafer structure Wa in the second state is delivered from the chuck table unit 12 to the lift-up hand unit 703. Then, the lift-up hand 703c of the lift-up hand unit 703 is moved in the X2 direction by the X-direction movement mechanism 703a. During this movement, the wafer ring structure W in the second state is inverted by the inversion mechanism 703d. The wafer ring structure W is placed in the first state in which the sheet member W2a is arranged on the lower side and the wafer W1 is arranged on the upper side. Then, the lift-up hand 703c of the lift-up hand unit 703 is moved in the Y1 direction by the X-direction movement mechanism 703a and is moved into the cassette unit 202. Then, the wafer structure Wa in the first state is delivered from the lift-up hand unit 703 to the cassette unit 202 and is stored in the cassette unit 202.

The semiconductor wafer processing apparatus 600 can also process the wafer ring structure W without inverting it. When the wafer ring structure W is not inverted, the lift-up hand 703c suctions and supports the wafer ring structure W from the Z1 direction side in the cassette unit 202. Then, the wafer ring structure W is supplied to the chuck table unit 12 by the lift-up hand unit 703 without being inverted. The remaining configurations of the fourth embodiment are similar to those of the first embodiment.

### Advantageous Effects of Fourth Embodiment

According to the fourth embodiment, the following advantageous effects are achieved.

According to the fourth embodiment, as described above, the lift-up hand unit 703 includes the inversion mechanism 703d configured to invert the posture of the wafer ring structure W. Accordingly, similarly to the first embodiment, the wafer ring structure W can be inverted by the inversion mechanism 703d while the complexity of the structure is reduced or prevented.

According to the fourth embodiment, as described above, the cassette unit 202 is configured to store the wafer ring structure W including the ring-shaped member W3 surrounding the wafer W1, and the lift-up hand unit 703 is configured to invert the wafer ring structure W using the inversion mechanism 703d and supply the wafer ring structure W to the dicing device 601. In the case of the wafer ring structure W including the ring-shaped member W3, the wafer W1 may not be supplied in a posture suitable for dicing. Therefore, with the configuration described above, even in the case of the wafer ring structure W including the ring-shaped member W3, in which the wafer W1 is not supplied in a posture suitable for dicing, the wafer W1 can be placed in a posture suitable for dicing by inverting the wafer ring structure W using the inversion mechanism 703d, and thus dicing can be performed appropriately.

According to the fourth embodiment, as described above, the wafer transporter includes the lift-up hand unit 703 configured to take out the wafer ring structure W from the cassette unit 202 and transport the taken-out wafer ring structure W, and the inversion mechanism 703d is provided in the lift-up hand unit 703. Accordingly, using the lift-up hand unit 703, the wafer ring structure W can be easily taken out from the cassette unit 202, and the taken-out wafer ring structure W can be easily transported. The remaining advantageous effects of the fourth embodiment are similar to those of the first embodiment.

### Modified Example of Fourth Embodiment

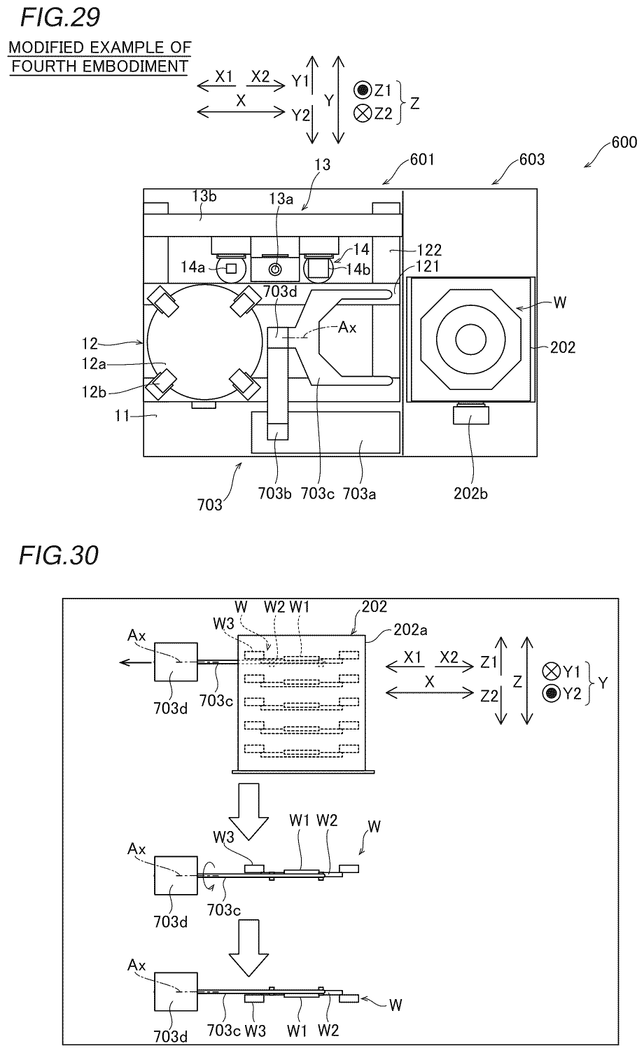

A modified example of the fourth embodiment is now described with reference to FIGS. 29 and 30. In the modified example, an example is described in which a lift-up hand 703c is rotated about a rotation axis Ax extending in an X direction by an inversion mechanism 703d, unlike the fourth embodiment in which the lift-up hand 703c is rotated about the rotation axis Ax extending in the Y direction by the inversion mechanism 703d.

As shown in FIGS. 29 and 30, in the modified example of the fourth embodiment, the inversion mechanism 703d rotates the lift-up hand 703c of a lift-up hand unit 703 that is suctioning a wafer ring structure W about the rotation axis Ax extending in a horizontal direction (X direction) to invert the posture of the wafer ring structure W. The inversion mechanism 703d includes a motor and a rotation shaft rotated by the motor. The rotation shaft of the inversion mechanism 703d is connected to the lift-up hand 703c so as to be able to rotate the lift-up hand 703c about the rotation axis Ax. The lift-up hand 703c is rotated on the spot about the rotation axis Ax by the inversion mechanism 703d.

The inversion of the wafer ring structure W in the modified example of the fourth embodiment is similar to that in the fourth embodiment, and thus detailed description thereof is omitted. However, the wafer ring structure W in the first state is taken out from a cassette unit 202 by the lift-up hand unit 703. During transportation to the chuck table unit 12, the wafer ring structure W in the first state is inverted by the inversion mechanism 703d. Then, the wafer ring structure W in the second state is supplied to the chuck table unit 12 by the lift-up hand unit 703. The subsequent operations are similar to those in the fourth embodiment. The remaining configurations of the modified example of the fourth embodiment are similar to those of the fourth embodiment.

### Fifth Embodiment

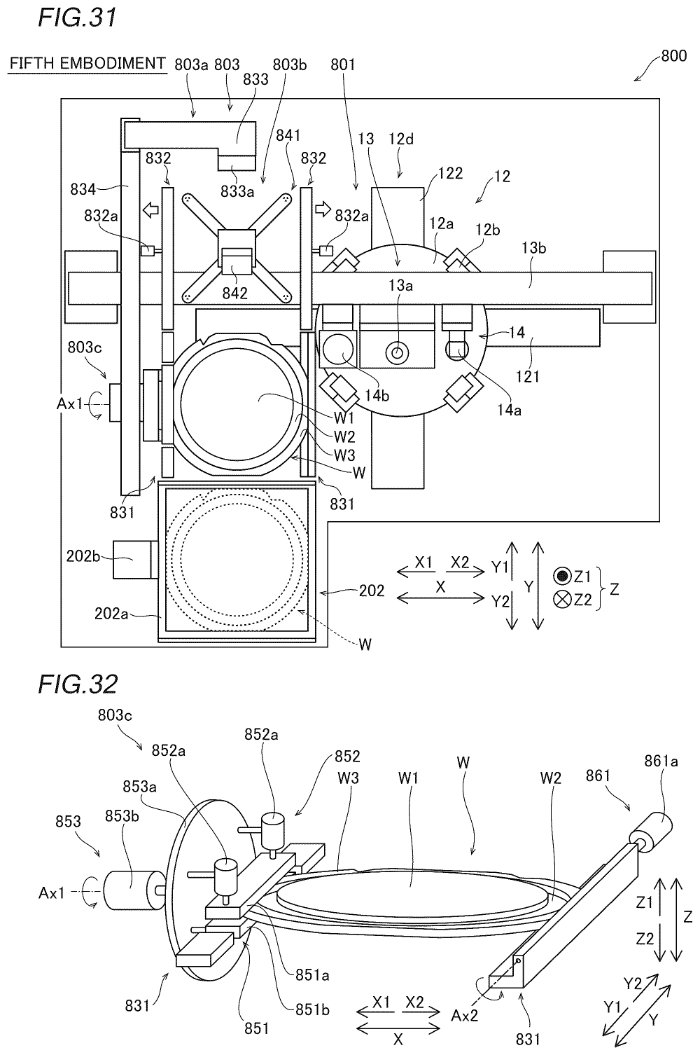

The configuration of a semiconductor wafer processing apparatus 800 according to a fifth embodiment is now described with reference to FIGS. 31 to 34. In the fifth embodiment, a conveyor 803a includes an inversion mechanism 803c, unlike the first to fourth embodiments. In the fifth embodiment, detailed description of the same or similar configurations as those of the first, second, third, or fourth embodiment is omitted. The semiconductor wafer processing apparatus 800 is an example of a “wafer processing apparatus” in the claims.

### Semiconductor Wafer Processing Apparatus

As shown in FIG. 31, the semiconductor wafer processing apparatus 800 is an apparatus that processes a wafer W1 provided on a wafer ring structure W.

The semiconductor wafer processing apparatus 800 includes a dicer 801, a cassette unit 202, and a wafer transporter 803. An upward-downward direction is defined as a Z direction, an upward direction is defined as a Z1 direction, and a downward direction is defined as a Z2 direction. A horizontal direction perpendicular to the Z direction is defined as an X direction, one direction in the X direction is defined as an X1 direction, and the other direction in the X direction is defined as an X2 direction. A horizontal direction perpendicular to the X direction is defined as a Y direction, one direction in the Y direction is defined as a Y1 direction, and the other direction in the Y direction is defined as a Y2 direction.

### Dicer

The dicer 801 emits a laser having a wavelength transmissive to the wafer W1 along a dividing line (street) to form a modified layer. Specifically, the dicer 801 includes a chuck table unit 12, a laser 13, and an imager 14.

### Cassette Unit

The cassette unit 202 can accommodate a plurality of wafer ring structures W each including a ring-shaped member W3 surrounding the wafer W1. In the fifth embodiment, the wafer ring structure W is stored in the cassette unit 202 such that a sheet member W2 is arranged on the lower side, the wafer W1 is arranged on the upper side, and a circuit layer W11 is arranged on the upper side. The cassette unit 202 includes wafer cassettes 202a, a Z-direction movement mechanism 202b, and pairs of placement portions 202c.

### Wafer Transporter

The wafer transporter 803 transports the wafer ring structure W between the cassette unit 202 and the dicer 801. Specifically, the wafer transporter 803 includes the conveyor 803a to take out the wafer ring structure W from the cassette unit 202 and transport the taken-out wafer ring structure W, and a suction hand unit 803b to transfer the wafer ring structure W transported by the conveyor 803a to the chuck table unit 12 of the dicer 801.

The conveyor 803a includes rails 831 and 832 to support the wafer ring structure W taken out from the cassette unit 202 from below, a clamp hand 833 to take out the wafer ring structure W from the cassette unit 202 and transport the wafer ring structure W on the rails 831 and 832, and a Y-direction movement mechanism 834 to move the clamp hand 833 in the Y direction.

The rails 831 and 832 are aligned in this order from the Y2 direction side toward the Y1 direction side. The rails 831 are arranged in the vicinity of the cassette unit 202. The rails 832 are arranged in the vicinity of the rails 831. The rails 831 and 832 extend in the Y direction. A pair of rails 831 and a pair of rails 832 are provided at a predetermined interval in the X direction. The pair of rails 832 include a rail drive mechanism 832a to change the interval in the X direction between the pair of rails 832. The rail drive mechanism 832a moves the pair of rails 832 away from each other in the X direction to increase the interval in the X direction between the pair of rails 832. The rail drive mechanism 832a moves the pair of rails 832 closer to each other in the X direction to decrease the interval in the X direction between the pair of rails 832. The rail drive mechanism 832a includes a cylinder (such as an air cylinder) provided on each of the pair of rails 832, for example.

The clamp hand 833 clamps and transports the wafer ring structure W. The clamp hand 833 transports the wafer ring structure W between three positions: a storage position of the wafer ring structure W in the cassette unit 202, an inversion position at which the posture of the wafer ring structure W is inverted by an inversion mechanism 803c described below, and a delivery position at which the wafer ring structure W is delivered to the suction hand unit 803b. The clamp hand 833 has a hook shape. The clamp hand 833 includes a clamp 833a at its tip end to clamp the wafer ring structure W. The clamp 833a clamps an end of the ring-shaped member W3 of the wafer ring structure W on the Y1 direction side in the upward-downward direction.

The Y-direction movement mechanism 834 moves the clamp hand 833 in the Y1 direction or the Y2 direction. The clamp hand 833 transports the wafer ring structure W by being moved by the Y-direction movement mechanism 834. The Y-direction movement mechanism 834 includes a linear conveyor module, or a ball screw and a drive including a motor with an encoder, for example.

The suction hand unit 803b includes a suction hand 841 to suction the wafer ring structure W, and a Z-direction movement mechanism 842 to move the suction hand 841 in the Z direction. The suction hand 841 generates a negative pressure to suction and support the wafer ring structure W. The suction hand 841 includes a suction hole or the like to suction the wafer ring structure W. The Z-direction movement mechanism 842 moves the suction hand 841 in the Z direction. The Z-direction movement mechanism 842 includes a linear conveyor module, or a ball screw and a drive including a motor with an encoder, for example.

In the fifth embodiment, the wafer transporter 803 includes the inversion mechanism 803c. Specifically, as shown in FIGS. 31 and 32, the inversion mechanism 803c is provided as a portion of the conveyor 803a. More specifically, the inversion mechanism 803c is provided as a portion of the rails 831. Moreover, the inversion mechanism 803c is provided as a portion of a first rail of the pair of rails 831.

The inversion mechanism 803c includes a holder 851 to hold the wafer ring structure W, a clamp drive mechanism 852 to drive the holder 851 in the upward-downward direction (Z direction), and a rotation drive mechanism 853 to rotationally drive the holder 851. The holder 851 is an example of a “clamp” in the claims.

The holder 851 is provided as a portion of the first rail of the pair of rails 831. The inversion mechanism 803c inverts the posture of the wafer ring structure W by rotating the holder 851 about a rotation axis Ax1 extending in the horizontal direction (X direction) while holding the wafer ring structure W using the holder 851. Specifically, the holder 851 clamps an end of the ring-shaped member W3 of the wafer ring structure W on the X1 direction side in the upward-downward direction (Z direction). The inversion mechanism 803c inverts the posture of the wafer ring structure W by rotating the holder 851 about the rotation axis Ax1 while clamping the end of the ring-shaped member W3 of the wafer ring structure W on the X1 direction side using the holder 851.

The holder 851 includes a first clamp member 851a that is a movable member, and a second clamp member 851b that is a fixed member. The first clamp member 851a and the second clamp member 851b face each other in the upward-downward direction (Z direction). The clamp drive mechanism 852 is connected to the first clamp member 851a. The clamp drive mechanism 852 drives the first clamp member 851a in the upward-downward direction such that the holder 851 clamps the wafer ring structure W between the first clamp member 851a and the second clamp member 851b. The clamp drive mechanism 852 includes cylinders 852a such as air cylinders as a drive source.

The rotation drive mechanism 853 includes a mounting member 853a and a motor 853b as a drive source to rotate the mounting member 853a. The clamp drive mechanism 852 and the second clamp member 851b are connected to the mounting member 853a. The first clamp member 851a is connected to the mounting member 853a via the clamp drive mechanism 852. The rotation drive mechanism 853 rotates the clamp drive mechanism 852, the first clamp member 851a, and the second clamp member 851b by rotating the mounting member 853a using the motor 853b. Thus, it is possible to rotate the first clamp member 851a and the second clamp member 851b while the wafer ring structure W is clamped between the first clamp member 851a and the second clamp member 851b, and thus it is possible to invert the posture of the wafer ring structure W. The motor 853b may be connected to the mounting member 853a via a belt pulley mechanism or the like.

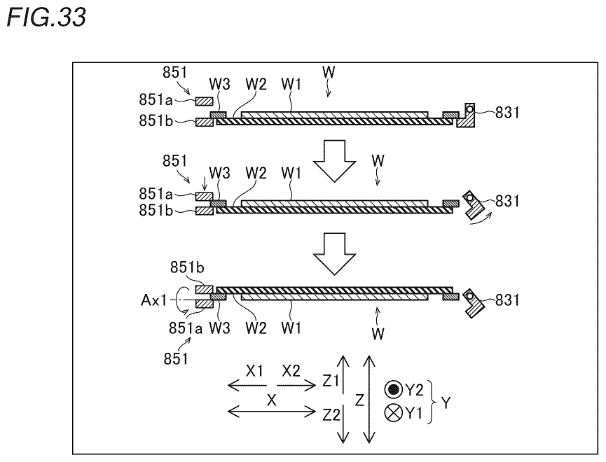

In the fifth embodiment, as shown in FIGS. 32 and 33, a second rail of the pair of rails 831 is retreated when the posture of the wafer ring structure W is inverted by the inversion mechanism 803c. Specifically, the second rail of the pair of rails 831 moves between an initial position at which the second rail supports the wafer ring structure W from below and a retreated position spaced apart from the wafer ring structure W by rotating about a rotation axis Ax2 extending along a direction (Y direction) in which the rails 831 extend. The second rail of the pair of rails 831 includes a retreat drive mechanism 861 to rotationally drive the pair of rails 831. The retreat drive mechanism 861 includes a rotary actuator 861a as a drive source.

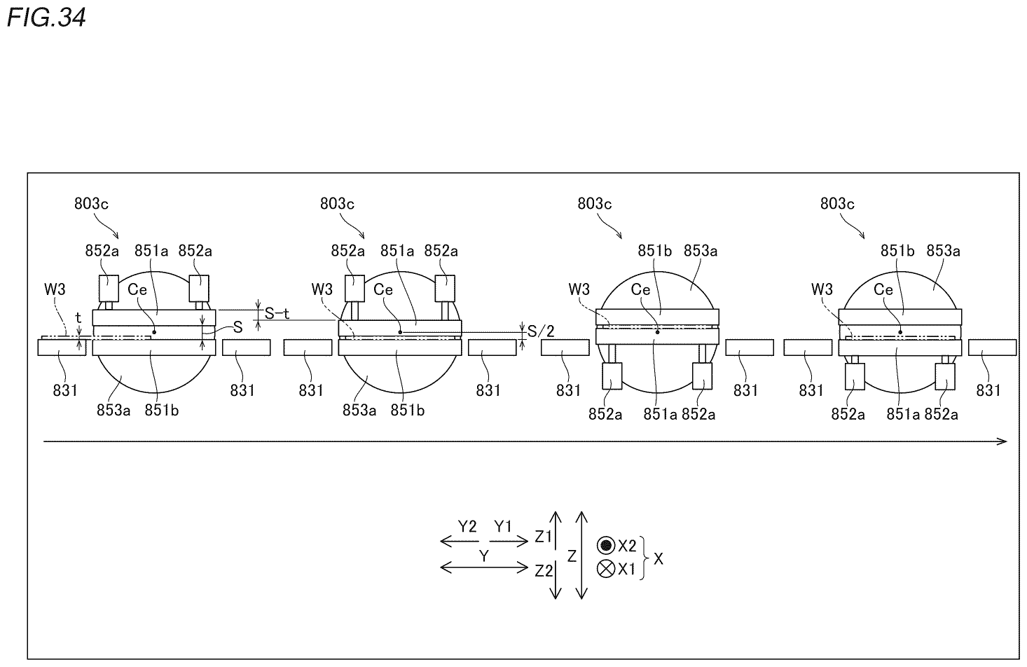

As shown in FIG. 34, when the stroke of the cylinders 852a is S, the rotation center Ce (rotation axis Ax1) of the inversion of the wafer ring structure W is located at a height position S/2 above support surfaces (upper surfaces) of the rails 831. Thus, it is possible to substantially align the height positions of support surfaces (upper surfaces) of the first clamp member 851a with the height positions of the support surfaces (upper surfaces) of the rails 831 in a state in which the wafer ring structure W is inverted and piston rods of the cylinders 852a are pulled back. The stroke amount S is equal to a distance between the first clamp member 851a and the second clamp member 851b, but because the ring-shaped member W3 has a thickness t, the piston rods of the cylinders 852a do not reach the stroke ends, and an actual stroke movement distance is S-t.

The height position of a support surface of the holder 851 of the inversion mechanism 803c that supports the ring-shaped member W3 of the wafer ring structure W from below is substantially aligned with the height positions of the support surfaces (upper surfaces) of the rails 831 in both the pre-inversion state and the post-inversion state of the wafer ring structure W. Thus, it is possible to smoothly transport the wafer ring structure W in both the pre-inversion state and the post-inversion state of the wafer ring structure W.

Specifically, in the pre-inversion state of the wafer ring structure W, the height position of a support surface (upper surface) of the second clamp member 851b that supports the ring-shaped member W3 of the wafer ring structure W from below is substantially aligned with the height positions of the support surfaces (upper surfaces) of the rails 831. Furthermore, in a state in which the piston rods of the cylinders 852a are pulled back in the post-inversion state of the wafer ring structure W, the height position of a support surface (upper surface) of the first clamp member 851a that supports the ring-shaped member W3 of the wafer ring structure W from below is substantially aligned with the height positions of the support surfaces (upper surfaces) of the rails 831.

In the fifth embodiment, the semiconductor wafer processing apparatus 800 can switch between a setting in which the posture of the wafer ring structure W is inverted by the inversion mechanism 803c and a setting in which the posture of the wafer ring structure W is not inverted by the inversion mechanism 803c based on information on the laser processing of the wafer W1. The information on the laser processing of the wafer W1 includes setting information on whether to perform the laser processing from the circuit surface side (the side on which the circuit layer W11 is present) of the wafer W1 or to perform the laser processing from the surface side (the side on which the circuit layer W11 is not present) of the wafer W1 opposite to the circuit surface through the sheet member W2. The information on the laser processing of the wafer W1 is set by a user and is stored in advance in a storage of the semiconductor wafer processing apparatus 800. When the laser processing is performed from the circuit surface side of the wafer W1, the setting is used in which the posture of the wafer ring structure W is not inverted by the inversion mechanism 803c. When the laser processing is performed through the sheet member W2 from the surface side of the wafer W1 opposite to the circuit surface, the setting is used in the posture of the wafer ring structure W is inverted by the inversion mechanism 803c.

### Operation of Semiconductor Wafer Processing Apparatus

The operation of the semiconductor wafer processing apparatus 800 according to the fifth embodiment is now described with reference to FIGS. 31 to 34.

As shown in FIG. 31, first, the wafer cassettes 202a are moved in the upward-downward direction by the Z-direction movement mechanism 202b such that the wafer ring structure W to be processed is located at a height position at which it can be taken out by the clamp hand 833. Then, the clamp hand 833 is moved to the storage position by the Y-direction movement mechanism 834, and the wafer ring structure W is clamped by the clamp hand 833. Then, in the case of the setting in which the posture of the wafer ring structure W is inverted by the inversion mechanism 803c, the wafer ring structure W is moved on the rails 831 by the clamp hand 833 and transported from the storage position to the inversion position.

As shown in FIGS. 32 and 33, the holder 851 holds the end of the ring-shaped member W3 of the wafer ring structure W on the X1 direction side, and the retreat drive mechanism 861 retreats the second rail of the pair of rails 831. That is, the cylinders 852a move the first clamp member 851a toward the second clamp member 851b such that the end of the ring-shaped member W3 of the wafer ring structure W on the X1 direction side is clamped between the first clamp member 851a and the second clamp member 851b. The rotary actuator 861a rotates the second rail of the pair of rails 831 away from the wafer ring structure W such that the second rail of the pair of rails 831 is moved from the initial position to the retreated position. At the retreated position, the second rail of the pair of rails 831 does not interfere with the inversion of the wafer ring structure W. When the wafer ring structure W is inverted, the clamp hand 833 releases its hold on the wafer ring structure W, and the clamp hand 833 is retreated by the Y-direction movement mechanism 834 to a position at which it does not interfere with the inversion of the wafer ring structure W.

Then, as shown in FIGS. 33 and 34, the holder 851 is rotated 180 degrees by the rotation drive mechanism 853. That is, the mounting member 853a is rotated 180 degrees by the motor 853b such that the clamp drive mechanism 852, the first clamp member 851a, and the second clamp member 851b are rotated 180 degrees. Thus, the wafer ring structure W held between the first clamp member 851a and the second clamp member 851b is inverted. Then, the second rail of the pair of rails 831 is returned from the retreated position to the initial position, and the holder 851 releases its hold on the wafer ring structure W. Furthermore, the clamp hand 833 is moved by the Y-direction movement mechanism 834 to a position at which it can hold the wafer ring structure W, and the wafer ring structure W is held by the clamp hand 833.

Then, as shown in FIG. 31, the wafer ring structure W is moved on the rails 831 and 832 by the clamp hand 833 and transported to the delivery position. In the case of the setting in which the posture of the wafer ring structure W is not inverted by the inversion mechanism 803c, the wafer ring structure W is transported by the clamp hand 833 from the storage position to the delivery position, passing through the inversion position without stopping at the inversion position.

Then, at the delivery position, the wafer ring structure W is delivered from the clamp hand 833 to the suction hand unit 803b. That is, the suction hand 841 is lowered by the Z-direction movement mechanism 842, and the ring-shaped member W3 of the wafer ring structure W is suctioned by the suction hand 841. Then, the suction hand 841 is raised by the Z-direction movement mechanism 842 such that the wafer ring structure W suctioned by the suction hand 841 is retreated from the rails 832. Then, the rail drive mechanism 832a increases the interval in the X direction between the pair of rails 832. Thus, it is possible to deliver the wafer ring structure W to the chuck table unit 12, which has been moved below the suction hand 841 and the rails 832 by the X-direction movement mechanism 121 and the Y-direction movement mechanism 122.

Then, the wafer ring structure W is delivered from the suction hand 841 to the chuck table unit 12. That is, the suction hand 841 is lowered below the rails 832 by the Z-direction movement mechanism 842, and the wafer ring structure W is placed on a suction unit 12a. Then, suction of the ring-shaped member W3 of the wafer ring structure W by the suction hand 841 is released, and the wafer ring structure W is suctioned by the suction unit 12a. Then, the suction hand 841 is raised by the Z-direction movement mechanism 842 such that the suction hand 841 is retreated from the chuck table unit 12.

Then, the wafer ring structure W is moved by the chuck table unit 12 to a position at which the laser 13 can emit a laser beam to the wafer W1. Then, the laser processing is performed on the wafer W1 of the wafer ring structure W. The details of the laser processing are similar to those in the first embodiment, and thus detailed description thereof is omitted. In the case of the setting in which the posture of the wafer ring structure W is inverted by the inversion mechanism 803c, the laser processing is performed from the surface side of the wafer W1 opposite to the circuit surface through the sheet member W2. This type of laser processing is effective when it is difficult to perform laser processing on the wafer W1 from the circuit surface side of the wafer W1 because the width of the street of the wafer W1 is narrow. In the case of the setting in which the posture of the wafer ring structure W is not inverted by the inversion mechanism 803c, the laser processing is performed from the circuit surface side of the wafer W1. In such a case, there is no need to invert the posture of the wafer ring structure W by the inversion mechanism 803c, and thus it is possible to shorten the cycle time as compared with a case in which the posture of the wafer ring structure W is inverted by the inversion mechanism 803c.

### Advantageous Effects of Fifth Embodiment

According to the fifth embodiment, the following advantageous effects are achieved.

According to the fifth embodiment, as described above, the wafer transporter 803 includes the inversion mechanism 803c configured to invert the posture of the wafer ring structure W. Accordingly, similarly to the first embodiment, the wafer ring structure W can be inverted by the inversion mechanism 803c while the complexity of the structure is reduced or prevented.

According to the fifth embodiment, as described above, the wafer transporter 803 includes the conveyor 803a configured to take out the wafer ring structure W from the cassette unit 202 and transport the taken-out wafer ring structure W, and the inversion mechanism 803c is provided as a portion of the conveyor 803a. Accordingly, the inversion mechanism 803c is provided as a portion of the conveyor 803a by effectively using the conveyor 803a that takes out the wafer ring structure W from the cassette unit 202, and thus as compared with a case in which the inversion mechanism 803c is provided separately and independently, the complexity of the structure can be reduced or prevented. Furthermore, the posture of the wafer ring structure W can be inverted while the wafer ring structure W is transported by the conveyor 803a, and thus no transportation loss of the wafer ring structure W occurs (the transportation path does not become long). Consequently, even when the posture of the wafer ring structure W is inverted, an increase in the cycle time can be reduced or prevented.

According to the fifth embodiment, as described above, the conveyor 803a includes the rails 831 configured to support, from below, the wafer ring structure W taken out from the cassette unit 202, and the inversion mechanism 803c is provided as a portion of the rails 831 of the conveyor 803a. Accordingly, the inversion mechanism 803c is provided as a portion of the conveyor 803a by effectively using the rails 831, and thus the complexity of the structure can be easily reduced or prevented.

According to the fifth embodiment, as described above, the pair of rails 831 are provided at the predetermined interval, the inversion mechanism 803c is provided as a portion of the first rail of the pair of rails 831, and the second rail of the pair of rails 831 is configured to be retreated when the posture of the wafer ring structure W is inverted by the inversion mechanism 803c. Accordingly, the inversion mechanism 803c is provided as a portion of the first rail of the pair of rails 831 such that the complexity of the structure can be reduced or prevented as compared with a case in which the inversion mechanism 803c is provided as a portion of both of the pair of rails 831. Furthermore, the second rail of the pair of rails 831 is retreated when the posture of the wafer ring structure W is inverted by the inversion mechanism 803c such that it is possible to prevent the second rail of the pair of rails 831 from interfering with the wafer ring structure W, and thus the posture of the wafer ring structure W can be easily inverted by the inversion mechanism 803c. Consequently, the posture of the wafer ring structure W can be easily inverted by the inversion mechanism 803c while the complexity of the structure is reduced or prevented.

According to the fifth embodiment, as described above, the second rail of the pair of rails 831 is configured to move between the initial position at which the second rail supports the wafer ring structure W from below and the retreated position spaced apart from the wafer ring structure W by rotating about the rotation axis Ax2 extending along the direction in which the rails 831 extend. Accordingly, with a simple configuration in which the second rail of the pair of rails 831 is simply rotated, the second rail of the pair of rails 831 can be retreated from the initial position to the retreated position. When the second rail of the pair of rails 831 is retreated from the initial position to the retreated position, a portion of the wafer ring structure W that is no longer supported from below by the second rail of the pair of rails 831 may be bent slightly downward. In this regard, the second rail of the pair of rails 831 is rotated such that the second rail of the pair of rails 831 is returned from the retreated position to the initial position, and thus even when the portion of the wafer ring structure W that is no longer supported from below by the second rail of the pair of rails 831 is bent slightly downward, the second rail of the pair of rails 831 can be easily returned to the initial position while the bent portion of the wafer ring structure W is lifted.

According to the fifth embodiment, as described above, the inversion mechanism 803c includes the holder 851 provided as a portion of the rails 831 and configured to hold the wafer ring structure W, and is configured to invert the posture of the wafer ring structure W by rotating the holder 851 while the wafer ring structure W is held by the holder 851. Accordingly, the holder 851 is provided by effectively using the rails 831 that support the wafer ring structure W from below, and thus the complexity of the structure is reduced or prevented, and the wafer ring structure W is easily held by the holder 851.

According to the fifth embodiment, as described above, the cassette unit 202 is configured to store the wafer ring structure W including the ring-shaped member W3 surrounding the wafer, and the inversion mechanism 803c includes the holder 851 provided as a portion of the first rail of the pair of rails 831 and configured to clamp the end of the ring-shaped member W3 of the wafer ring structure W in the upward-downward direction, and is configured to invert the posture of the wafer ring structure W by rotating the holder 851 while the end of the ring-shaped member W3 of the wafer ring structure W is clamped by the holder 851. Accordingly, the holder 851 is provided by effectively using the first rail of the pair of rails 831 that support the wafer ring structure W from below, and thus the complexity of the structure can be reduced or prevented. Furthermore, the end of the ring-shaped member W3 of the wafer ring structure W is clamped by the holder 851 such that the wafer ring structure W can be reliably held, and thus the posture of the wafer ring structure W can be stably inverted.

According to the fifth embodiment, as described above, the semiconductor wafer processing apparatus is configured to switch between the setting in which the posture of the wafer ring structure W is inverted by the inversion mechanism 803c and the setting in which the posture of the wafer ring structure W is not inverted by the inversion mechanism 803c based on the information on the laser processing of the wafer W1. Accordingly, depending on the wafer W1 to be processed, it is possible to switch between the laser processing from the circuit surface side of the wafer W1 and the laser processing from the surface side of the wafer W1 opposite to the circuit surface. Consequently, it is possible to improve the degree of freedom in processing the wafer W1. The remaining advantageous effects of the fifth embodiment are similar to those of the first embodiment.

### Modified Examples

The embodiments disclosed this time must be considered as illustrative in all points and not restrictive. The scope of the present disclosure is not shown by the above description of the embodiments but by the scope of claims for patent, and all modifications (modified examples) within the meaning and scope equivalent to the scope of claims for patent are further included.

For example, while the example in which the wafer transporter includes the suction hand that suctions and supports the wafer structure, and the inversion mechanism inverts the suction hand that is suctioning the wafer structure has been shown in each of the aforementioned first to fourth embodiments, the present disclosure is not restricted to this. In the present disclosure, the wafer transporter may include a support other than the suction unit that supports the wafer structure, and the inversion mechanism may invert the support that is supporting the wafer structure.

While the example in which the semiconductor wafer processing apparatus includes the temporary placement unit has been shown in the aforementioned third embodiment, the present disclosure is not restricted to this. In the present disclosure, in the case of a wafer structure not including a ring-shaped member, the wafer processing apparatus may not include the temporary placement unit. In such a case, the wafer structure can be inverted by the inversion mechanism and directly supplied to the dicer.

While the example in which the semiconductor wafer processing apparatus includes the imager to image the wafer of the wafer structure placed on the temporary placement unit has been shown in the aforementioned third embodiment, the present disclosure is not restricted to this. In the present disclosure, even when the semiconductor wafer processing apparatus includes the temporary placement unit, the semiconductor wafer processing apparatus may not include the imager to image the wafer of the wafer structure placed on the temporary placement unit.

While the example in which the semiconductor wafer processing apparatus includes the ultraviolet irradiator and the squeegee unit has been shown in each of the aforementioned first and second embodiments, the present disclosure is not restricted to this. In the present disclosure, even when the semiconductor wafer processing apparatus includes the expander, the semiconductor wafer processing apparatus may not include the ultraviolet irradiator and the squeegee unit.

While the example in which the wafer transporter inverts the wafer structure using the inversion mechanism and delivers the wafer structure to the cool air supplier has been shown in each of the aforementioned first and second embodiments, the present disclosure is not restricted to this. In the present disclosure, the wafer transporter may invert the wafer structure using the inversion mechanism and deliver the wafer structure to a receiving portion other than the cool air supplier.

While the control process is described, using the flowchart described in a manner driven by a flow in which processes are performed in order along a process flow for the convenience of illustration in each of the aforementioned first and second embodiments, the present disclosure is not restricted to this. In the present disclosure, the control process may be performed in an event-driven manner in which processes are performed on an event basis. In this case, the control process may be performed in a complete event-driven manner or in a combination of an event-driven manner and a manner driven by a flow.

While the example in which the inversion mechanism is provided as a portion of the first rail of the pair of rails has been shown in the aforementioned fifth embodiment, the present disclosure is not restricted to this. In the present disclosure, the inversion mechanism may be provided as a portion of both of the pair of rails. That is, the holder of the inversion mechanism may be provided as a portion of both of the pair of rails.

While the example in which the holder of the inversion mechanism is the clamp unit that clamps the wafer structure has been shown in the aforementioned fifth embodiment, the present disclosure is not restricted to this. In the present disclosure, the holder of the inversion mechanism may be a suction unit that suctions the wafer structure.

While the example in which the second rail of the pair of rails rotates to move between the initial position and the retreated position has been shown in the aforementioned fifth embodiment, the present disclosure is not restricted to this. In the present disclosure, the second rail of the pair of rails may slide to move between the initial position and the retreated position.

What is claimed is:

1. A wafer processing apparatus comprising:
a wafer storage configured to store a wafer structure including a wafer on which a plurality of semiconductor chips have been formed and a sheet member to which the wafer has been attached;
a dicer configured to perform dicing to divide the wafer of the wafer structure supplied from the wafer storage into individual semiconductor chips; and
a wafer transporter configured to transport the wafer structure between the wafer storage and the dicer; wherein
the wafer transporter includes an inversion mechanism configured to invert a posture of the wafer structure.

2. The wafer processing apparatus according to claim 1, wherein
the wafer transporter further includes a suction unit configured to suction the wafer structure; and
the inversion mechanism is configured to invert the posture of the wafer structure by rotating the suction unit that is suctioning the wafer structure about a rotation axis extending in a horizontal direction.

3. The wafer processing apparatus according to claim 1, wherein
the wafer storage is configured to store the wafer structure that does not include a ring-shaped member surrounding the wafer; and
the wafer transporter is configured to invert the wafer structure using the inversion mechanism and supply the wafer structure to the dicer.

4. The wafer processing apparatus according to claim 3, further comprising:
a temporary placement unit between the wafer storage and the dicer and configured to allow the wafer structure to be placed thereon; wherein
the wafer transporter is configured to invert the wafer structure using the inversion mechanism and place the wafer structure on the temporary placement unit before supplying the wafer structure to the dicer.

5. The wafer processing apparatus according to claim 1, further comprising:
an expander configured to expand the sheet member to which the wafer diced by the dicer has been attached; wherein
the wafer transporter is configured to transport the wafer structure between the dicer and the expander;
the wafer storage is configured to store the wafer structure including a ring-shaped member surrounding the wafer; and
the wafer transporter is configured to supply the wafer structure to the dicer without inverting the wafer structure using the inversion mechanism, and to invert the wafer structure using the inversion mechanism and supply the wafer structure to the expander.

6. The wafer processing apparatus according to claim 5, wherein
the expander includes a cooler configured to cool the sheet member when expanding the sheet member; and
the wafer transporter is configured to invert the wafer structure using the inversion mechanism and deliver the wafer structure to the cooler.

7. The wafer processing apparatus according to claim 1, wherein
the wafer storage is configured to store the wafer structure including a ring-shaped member surrounding the wafer; and
the wafer transporter is configured to invert the wafer structure using the inversion mechanism and supply the wafer structure to the dicer.

8. The wafer processing apparatus according to claim 1, wherein
the wafer transporter includes a removing unit configured to take out the wafer structure from the wafer storage, and a transport mechanism configured to transport a taken-out wafer structure; and
the inversion mechanism is in the transport mechanism.

9. The wafer processing apparatus according to claim 1, wherein
the wafer transporter includes a removing transporter configured to take out the wafer structure from the wafer storage and transport a taken-out wafer structure; and
the inversion mechanism is in the removing transporter.

10. The wafer processing apparatus according to claim 1, wherein
the wafer transporter includes a conveyor configured to take out the wafer structure from the wafer storage and transport a taken-out wafer structure; and
the inversion mechanism is configured as a portion of the conveyor.

11. The wafer processing apparatus according to claim 10, wherein
the conveyor includes a rail configured to support, from below, the wafer structure taken out from the wafer storage; and
the inversion mechanism is configured as a portion of the rail.

12. The wafer processing apparatus according to claim 11, wherein
the rail includes a pair of rails positioned at a predetermined interval;
the inversion mechanism is configured as a portion of a first rail of the pair of rails; and
a second rail of the pair of rails is configured to be retreated when the posture of the wafer structure is inverted by the inversion mechanism.

13. The wafer processing apparatus according to claim 12, wherein the second rail of the pair of rails is configured to move between an initial position at which the second rail supports the wafer structure from below and a retreated position spaced apart from the wafer structure by rotating about a rotation axis extending along a direction in which the pair of rails extend.

14. The wafer processing apparatus according to claim 11, wherein the inversion mechanism includes a holder configured as a portion of the rail and configured to hold the wafer structure, and is configured to invert the posture of the wafer structure by rotating the holder while the wafer structure is held by the holder.

15. The wafer processing apparatus according to claim 12, wherein
the wafer storage is configured to store the wafer structure including a ring-shaped member surrounding the wafer; and
the inversion mechanism includes a clamp unit configured as a portion of the first rail of the pair of rails and configured to clamp an end of the ring-shaped member of the wafer structure in an upward-downward direction, and is configured to invert the posture of the wafer structure by rotating the clamp unit while the end of the ring-shaped member of the wafer structure is clamped by the clamp unit.

16. The wafer processing apparatus according to claim 10, wherein the wafer processing apparatus is configured to switch between a setting in which the posture of the wafer structure is inverted by the inversion mechanism and a setting in which the posture of the wafer structure is not inverted by the inversion mechanism based on information on laser processing of the wafer.

17. A semiconductor chip manufacturing method comprising:
performing, using a dicer, dicing to divide, into individual semiconductor chips, a wafer of a wafer structure including the wafer on which a plurality of semiconductor chips have been formed and a sheet member to which the wafer has been attached and supplied from a wafer storage configured to store the wafer structure; and
transporting, using a wafer transporter, the wafer structure between the wafer storage and the dicer; wherein
the wafer transporter includes an inversion mechanism configured to invert a posture of the wafer structure.

18. A semiconductor chip manufactured by a wafer processing apparatus, the wafer processing apparatus comprising:
a wafer storage configured to store a wafer structure including a wafer on which a plurality of semiconductor chips have been formed and a sheet member to which the wafer has been attached;
a dicer configured to perform dicing to divide the wafer of the wafer structure supplied from the wafer storage into individual semiconductor chips; and
a wafer transporter configured to transport the wafer structure between the wafer storage and the dicer; wherein
the wafer transporter includes an inversion mechanism configured to invert a posture of the wafer structure.
